(19) United States
(12) Patent Application Publication
(10) Pub. No.: US 2024/0319592 A1
(43) Pub. Date: Sep. 26, 2024

(54) RESIST COMPOSITION AND METHOD OF FORMING PATTERN USING THE SAME

(71) Applicant: Samsung Electronics Co., Ltd., Suwon-si (KR)

(72) Inventors: Changheon LEE, Suwon-si (KR); Haengdeog KOH, Suwon-si (KR); Yoonhyun KWAK, Suwon-si (KR); Mijeong KIM, Suwon-si (KR); Sunyoung LEE, Suwon-si (KR); Kyuhyun IM, Suwon-si (KR); Jinwon JEON, Suwon-si (KR); Jungha CHAE, Suwon-si (KR); Sunghyun HAN, Suwon-si (KR)

(73) Assignee: Samsung Electronics Co., Ltd., Suwon-si (KR)

(21) Appl. No.: 18/491,310

(22) Filed: Oct. 20, 2023

(30) Foreign Application Priority Data
Mar. 24, 2023 (KR) 10-2023-0039144
May 10, 2023 (KR) 10-2023-0060703

(51) Int. Cl. G03F 7/004; G03F 7/038

(52) U.S. Cl. CPC G03F 7/0042; G03F 7/0048; G03F 7/0382

(57) ABSTRACT

Provided are a resist composition and a method of forming a pattern using the same, wherein the resist composition may include an organometallic compound represented by Formula 1 below, and a polymer including a repeating unit represented by Formula 2 below.

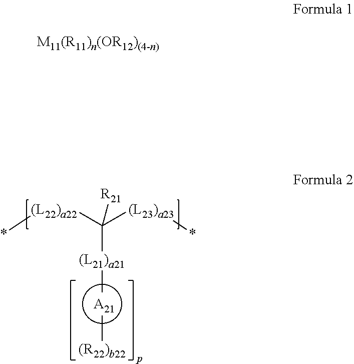

For a description of M₁₁, R₁₁, R₁₂, n, A₂₁, L₂₁ to L₂₃, A₂₁ to a23, R₂₁ to R₂₂, b22, and p in Formula 1 and Formula 2, the specification is referred to.

### CROSS-REFERENCE TO RELATED APPLICATION

This application is based on and claims priority under 35 U.S.C. § 119 to Korean Patent Application Nos. 10-2023-0039144, filed on Mar. 24, 2023, and 10-2023-0060703, filed on May 10, 2023 in the Korean Intellectual Property Office, the disclosures of each of which are incorporated by reference herein in their entirety.

### BACKGROUND

### 1. Field

The disclosure relates to a resist composition and a method of forming a pattern using the same.

### 2. Description of the Related Art

During the manufacturing of semiconductors, resists of which physical properties change in response to light are being used to form fine patterns. Among the resists, chemically amplified resists have been widely used. In chemically amplified resists, acids formed when light reacts with photoacid generators react again with base resins to change the solubility of the base resins in developing solutions, thereby enabling patterning.

However, in the case of a chemically amplified resist, a formed acid may diffuse to an unexposed region, which may cause a problem such as a reduction in uniformity of patterns or an increase in surface roughness. In addition, as semiconductor processes become increasingly miniaturized, since acid diffusion is not easy to control, there is a need to develop a new type of resist.

Recently, attempts have been made to develop materials of which physical properties are changed by exposure in order to overcome limitations of chemically amplified resists. However, there may still a problem that a dose required for exposure is high.

### SUMMARY

Provided are a resist composition of which physical properties are changed even by exposure at a low dose and which provides a pattern with improved resolution, and a method of forming a pattern using the same.

Additional aspects will be set forth in part in the description which follows and, in part, will be apparent from the description, or may be learned by practice of the presented embodiments of the disclosure.

According to an embodiment of the disclosure, a resist composition includes an organometallic compound represented by Formula 1 below, and a polymer including a repeating unit represented by Formula 2 below:

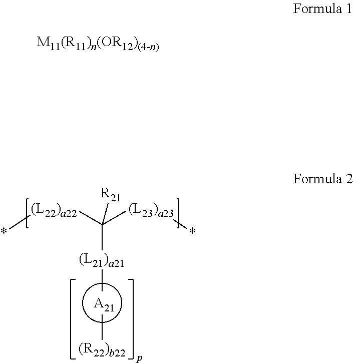

In Formula 1 and Formula 2,
M₁₁ may be indium (In), tin (Sn), antimony (Sb), tellurium (Te), thallium (Tl), lead (Pb), bismuth (Bi), silver (Ag), or polonium (Po),
R₁₁ may be a linear, branched, or cyclic C₁-C₃₀ monovalent hydrocarbon group which may optionally include a heteroatom,
R₁₂ may be a linear, branched, or cyclic C₁-C₃₀ monovalent hydrocarbon group, which may optionally include a heteroatom, or *-M₁₂(R₁₃)ₘ(OR₁₄)₍₃₋ₘ₎, n may be an integer from 1 to 4,
M₁₂ may be indium (In), tin (Sn), antimony (Sb), tellurium (Te), thallium (Tl), lead (Pb), bismuth (Bi), silver (Ag), or polonium (Po),
R₁₃ and R₁₄ may each independently be a linear, branched, or cyclic C₁-C₃₀ monovalent hydrocarbon group which may optionally include a heteroatom,
m may be an integer from 0 to 3,
L₂₁ to L₂₃ may each independently be a single bond, O, S, C(═O), C(═O)O, OC(═O), C(═O)NH, NHC(═O), or a linear, branched, or cyclic C₁-C₃₀ divalent hydrocarbon group which may optionally include a heteroatom,
a21 to a23 may each independently be an integer from 1 to 4,
A₂₁ may be a cyclic C₁-C₃₀ hydrocarbon group including a heteroatom,
R₂₁ and R₂₂ may each independently be: hydrogen; deuterium; halogen; or a linear, branched, or cyclic C₁-C₃₀ monovalent hydrocarbon group which may optionally include a heteroatom,
b22 may be an integer from 1 to 10,
p may be an integer from 1 to 5, and
* may be a binding site with an adjacent atom.

According to an embodiment of the disclosure, a resist composition includes an organometallic compound represented by Formula 1 below, and a monomer represented by Formula 20 below:

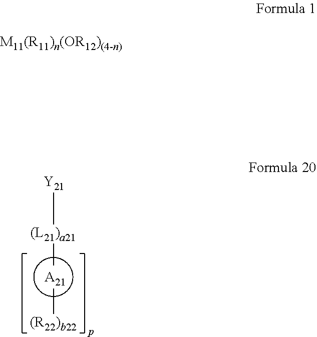

In Formula 1 and Formula 20,
M₁₁ may be indium (In), tin (Sn), antimony (Sb), tellurium (Te), thallium (Tl), lead (Pb), bismuth (Bi), silver (Ag), or polonium (Po),
R₁₁ may be a linear, branched, or cyclic C₁-C₃₀ monovalent hydrocarbon group which may optionally include a heteroatom,
R₁₂ may be a linear, branched, or cyclic C₁-C₃₀ monovalent hydrocarbon group, which may optionally include a heteroatom, or *-M₁₂(R₁₃)ₘ(OR₁₄)₍₃₋ₘ₎,
n may be an integer from 1 to 4, M₁₂ may be indium (In), tin (Sn), antimony (Sb), tellurium (Te), thallium (Tl), lead (Pb), bismuth (Bi), silver (Ag), or polonium (Po),
R₁₃ and R₁₄ may each independently be a linear, branched, or cyclic C₁-C₃₀ monovalent hydrocarbon group which may optionally include a heteroatom,
m may be an integer from 0 to 3,
Y₂₁ may be a polymerizable group,
L₂₁ may be a single bond, O, S, C(═O), C(═O)O, OC(═O), C(═O)NH, NHC(═O), or a linear, branched, or cyclic C₁-C₃₀ divalent hydrocarbon group which may optionally include a heteroatom, a21 may be an integer from 1 to 4,
A₂₁ may be a cyclic C₁-C₃₀ hydrocarbon group including a heteroatom,
R₂₂ may be hydrogen, deuterium, halogen, or a linear, branched, or cyclic C₁-C₃₀ monovalent hydrocarbon group which may optionally include a heteroatom,
b22 may be an integer from 1 to 10, and
p may be an integer from 1 to 5.

According to an embodiment of the disclosure, a method of forming a pattern includes applying any one of the above-described resist compositions to form a resist film, exposing at least a portion of the resist film to high energy rays to provide an exposed resist film, and developing the exposed resist film using a developing solution.

### BRIEF DESCRIPTION OF THE DRAWINGS

The above and other aspects, features, and advantages of certain embodiments will be more apparent from the following description taken in conjunction with the accompanying drawings, in which:

FIG. 1 is a flowchart illustrating a method of forming a pattern according to an embodiment;

FIGS. 2A to 2C are side cross-sectional views illustrating the method of forming a pattern according to the embodiment;

FIGS. 3A to 3D show ¹H-NMR and ¹¹⁹Sn-NMR spectra of Compound FB and Compound T1;

FIGS. 4A and 4B are graphs of Comparative Example 1 and Example 1, respectively;

FIG. 5A is a graph of Comparative Example 1 (corresponding to 0 day in FIG. 5A) and Comparative Example 3 (corresponding to 7 days in FIG. 5A);

FIG. 5B is a graph of Example 1 (corresponding to 0 day in FIG. 5B) and Example 3 (corresponding to 7 days in FIG. 5B);

FIGS. 6A and 6B are graphs of Example 4 and Example 5, respectively;

FIGS. 7A to 7E are side cross-sectional views illustrating a method of forming a patterned structure according to an embodiment; and

FIGS. 8A to 8E are side cross-sectional views illustrating a method of forming a semiconductor device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Since the disclosure can apply various transformations and have various embodiments, specific embodiments will be illustrated in the drawings and described in detail in the detailed description. However, it should be understood that this is not intended to limit the disclosure to specific embodiments, and includes all transformations, equivalents, and substitutes included in the spirit and scope of the disclosure. In describing the disclosure, when it is determined that the specific description of the known related art unnecessarily obscures the gist of the disclosure, the detailed description thereof will be omitted.

It will be understood that, although the terms “first,” “second,” and “third” may be used herein to describe various elements, these elements should not be limited by these terms. These terms are only used to distinguish one element from another element and not used to limit order or types of elements.

In the present specification, when a portion of a layer, film, region, plate, or the like is described as being “on” or “above” another portion, it may include not only the meaning of “immediately on/under/to the left/to the right in a contact manner,” but also the meaning of “on/under/to the left/to the right in a non-contact manner.”

An expression used in the singular encompasses the expression of the plural, unless it has a clearly different meaning in the context. Hereinafter, unless explicitly described to the contrary, it is to be understood that the terms such as “including,” “having,” and “comprising” are intended to indicate the existence of the features, numbers, steps, actions, components, parts, ingredients, materials, or combinations thereof disclosed in the specification and are not intended to preclude the possibility that one or more other features, numbers, steps, actions, components, parts, ingredients, materials, or combinations thereof may exist or may be added.

Whenever a range of values is recited, the range includes all values that fall within the range as if expressly written, and the range further includes the boundaries of the range. Thus, a range of “X to Y” includes all values between X and Y and also includes X and Y.

As used herein, “Cₓ-C_{y}” means that the number of carbon atoms constituting a substituent is in a range of x to y. For example, “C₁-C₆” means that the number of carbon atoms constituting a substituent is in a range of 1 to 6, and “C₆-C₂₀” means that the number of carbon atoms constituting a substituent is in a range of 6 to 20.

As used herein, the term “monovalent hydrocarbon group” may refer to a monovalent residue derived from an organic compound including carbon and hydrogen or a derivative thereof, and specific examples thereof may include linear or branched alkyl groups (for example, a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, and a nonyl group), monovalent saturated cycloaliphatic hydrocarbon groups (cycloalkyl groups) (for example, a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group), a monovalent unsaturated aliphatic hydrocarbon group (alkenyl group or alkynyl group) (for example, an allyl group), a monovalent unsaturated cycloaliphatic hydrocarbon group (cycloalkenyl group) (for example, 3-cyclohexenyl), aryl groups (for example, a phenyl group, a 1-naphthyl group, and a 2-naphthyl group); arylalkyl groups (for example, a benzyl group and a diphenylmethyl group), heteroatom-containing monovalent hydrocarbon groups (for example, a tetrahydrofuranyl group, a methoxymethyl group, an ethoxymethyl group, a methylthiomethyl group, an acetamidemethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group), and any combination thereof. In addition, in these groups, some hydrogen atoms may be substituted by a moiety including a heteroatom such as oxygen, sulfur, nitrogen, or halogen, or some carbon atoms may be substituted by a moiety including a heteroatom such as oxygen, sulfur, or nitrogen so that the groups may include a hydroxy group, a cyano group, a carbonyl group, a carboxyl group, an ether bond, an ester bond, a sulfonate ester bond, carbonate, a lactone ring, a sultone ring, a carboxylic anhydride moiety, or a haloalkyl moiety.

As used herein, the term “divalent hydrocarbon group” is a divalent residue and means that any one hydrogen atom of the monovalent hydrocarbon group is replaced with a bonding site with an adjacent atom. The divalent hydrocarbon group may include, for example, a linear or branched alkylene group, a cycloalkylene group, an alkenylene group, an alkynylene group, a cycloalkylene group, an arylene group, a group in which some carbon atoms thereof are replaced with a heteroatom, and the like.

As used herein, the term “alkyl group” refers to a linear or branched saturated aliphatic hydrocarbon monovalent group, and specific examples thereof include a methyl group, an ethyl group, a propyl group, an isobutyl group, a sec-butyl group, a tert-butyl group, a pentyl group, an iso-amyl group, a hexyl group, and the like. As used herein, the term “alkylene group” refers to a linear or branched saturated aliphatic hydrocarbon divalent group, and specific examples thereof include a methylene group, an ethylene group, a propylene group, a butylene group, an isobutylene group, and the like.

As used herein, the term “halogenated alkyl group” refers to a group in which one or more hydrogen atoms of an alkyl group are substituted with halogen, and specific examples thereof include CF₃ and the like.

As used herein, the term “alkoxy group” refers to a monovalent group having a formula of—OA₁₀₁, wherein A₁₀₁ is an alkyl group. Specific examples thereof include a methoxy group, an ethoxy group, an isopropyloxy group, and the like.

As used herein, the term “alkylthio group” refers to a monovalent group having a formula of—SA₁₀₁, wherein A₁₀₁ is an alkyl group.

As used herein, the term “halogenated alkoxy group” refers to a group in which one or more hydrogen atoms of an alkoxy group are substituted with halogen, and specific examples thereof include —OCF₃ and the like.

As used herein, the term “halogenated alkylthio group” refers to a group in which one or more hydrogen atoms of an alkylthio group are substituted with halogen, and specific examples thereof include —SCF₃ and the like.

As used herein, the term “cycloalkyl group” refers to a monovalent saturated hydrocarbon cyclic group, and specific examples thereof include monocyclic groups such as a cyclopropyl group, a cyclobutyl group, a cyclopentyl group, a cyclohexyl group, and a cycloheptyl group, and polycyclic condensed cyclic groups such as a norbornyl group and an adamantyl group. As used herein, the term “cycloalkylene group” refers to a divalent saturated hydrocarbon cyclic group, and specific examples thereof include a cyclopentylene group, a cyclohexylene group, an adamantylene group, an adamantylmethylene group, a norbornylene group, a norbornylmethylene group, a tricyclodecanylene group, a tetracyclododecanylene group, a tetracyclododecanylmethylene group, a dicyclohexylmethylene group, and the like.

As used herein, the term “cycloalkoxy group” refers to a monovalent group having a formula of—OA₁₀₂, wherein A₁₀₂ is a cycloalkyl group. Specific examples thereof include a cyclopropoxy group, a cyclobutoxy group, and the like.

As used herein, the term “cycloalkylthio group” refers to a monovalent group having a formula of—SA₁₀₂, wherein A₁₀₂ is a cycloalkyl group.

As used herein, the term “heterocycloalkyl group” may be a group in which some carbon atoms of the cycloalkyl group are replaced by a moiety including a heteroatom, for example, oxygen, sulfur, or nitrogen, and specifically, the heterocycloalkyl group may include an ether bond, an ester bond, a sulfonate ester bond, carbonate, a lactone ring, a sultone ring, or a carboxylic anhydride moiety. As used herein, the term “heterocycloalkylene group” is a group in which some carbon atoms of the cycloalkylene group are replaced by a moiety including a heteroatom, for example, oxygen, sulfur, or nitrogen.

As used herein, the term “heterocycloalkoxy group” refers to a monovalent group having a formula of—OA₁₀₃, wherein A₁₀₃ is a heterocycloalkyl group.

As used herein, the term “alkenyl group” refers to a linear or branched unsaturated aliphatic hydrocarbon monovalent group including one or more carbon-carbon double bonds. As used herein, the term “alkenylene group” refers to a linear or branched unsaturated aliphatic hydrocarbon divalent group including one or more carbon-carbon double bonds.

As used herein, the term “alkenyloxy group” refers to a monovalent group having a formula of—OA₁₀₄, wherein A₁₀₄ is an alkenyl group.

As used herein, the term “cycloalkenyl group” refers to a monovalent unsaturated hydrocarbon cyclic group including one or more carbon-carbon double bonds. As used herein, the term “cycloalkenylene group” refers to a divalent unsaturated hydrocarbon cyclic group including one or more carbon-carbon double bonds.

As used herein, the term “cycloalkenyloxy group” refers to a monovalent group having a formula of—OA₁₀₅, wherein A₁₀₅ is a cycloalkenyl group.

As used herein, the term “heterocycloalkenyl group” is a group in which some carbon atoms of the cycloalkenylene group are replaced by a moiety including a heteroatom, for example, oxygen, sulfur, or nitrogen. As used herein, the term “heterocycloalkenylene group” is a group in which some carbon atoms of the cycloalkenylene group are replaced by a moiety including a heteroatom, for example, oxygen, sulfur, or nitrogen.

As used herein, the term “heterocycloalkenyloxy group” refers to a monovalent group having a formula of—OA₁₀₆, wherein A₁₀₆ is a heterocycloalkenyl group.

As used herein, the term “alkynyl group” refers to a linear or branched unsaturated aliphatic hydrocarbon monovalent group including one or more carbon-carbon triple bonds.

As used herein, the term “alkynyloxy group” refers to a monovalent group having a formula of—OA₁₀₇, wherein A₁₀₇ is an alkynyl group.

As used herein, the term “aryl group” refers to a monovalent group having a carbocyclic aromatic system, and specific examples thereof include a phenyl group, a naphthyl group, an anthracenyl group, a phenanthrenyl group, a pyrenyl group, a chrysenyl group, and the like.

As used herein, the term “aryloxy group” refers to a monovalent group having a formula of—OA₁₀₈, wherein A₁₀₈ is an aryl group.

As used herein, the term “heteroaryl group” refers to a monovalent group having a heterocyclic aromatic system, and specific examples thereof include a pyridinyl group, a pyrimidinyl group, a pyrazinyl group, and the like. As used herein, the term “heteroarylene group” refers to a divalent group having a heterocyclic aromatic system.

As used herein, the term “heteroaryloxy group” refers to a monovalent group having a formula of—OA₁₀₉, wherein A₁₀₉ is a heteroaryl group.

As used herein, the term “substituent” includes: deuterium, halogen, a hydroxyl group, a cyano group, a nitro group, a carbonyl group, a carboxylic acid group, an amino group, an ether moiety, an ester moiety, a sulfonate ester moiety, a carbonate moiety, amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₅-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, or a C₁-C₂₀ heteroarylthio group;

a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₅-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, and a C₁-C₂₀ heteroarylthio group, each substituted with deuterium, halogen, a hydroxyl group, a cyano group, a nitro group, a carbonyl group, a carboxylic acid group, an amino group, an ether moiety, an ester moiety, a sulfonate ester moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₅-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, a C₁-C₂₀ heteroarylthio group, and any combination thereof; and any combination thereof.

Hereinafter, embodiments will be described in detail with reference to the accompanying drawings, wherein like reference numerals denote substantially the same or corresponding components throughout the drawings, and a redundant description thereof will be omitted. In the drawings, the thicknesses of layers and regions are exaggerated for clarity. Also, in the drawings, the thicknesses of some layers and regions are exaggerated for convenience of description. Meanwhile, embodiments set forth herein are merely examples and various changes may be made therein.

### [Resist Composition and Polymer Included]

A resist composition according to embodiments may include: an organometallic compound represented by Formula 1 below and a polymer including a repeating unit represented by Formula 2 below:

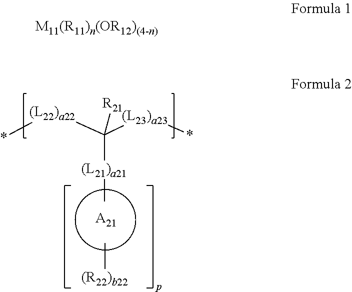

In Formula 1 and Formula 2,
M₁₁ may be indium (In), tin (Sn), antimony (Sb), tellurium (Te), thallium (Tl), lead (Pb), bismuth (Bi), silver (Ag), or polonium (Po),
R₁₁ may be a linear, branched, or cyclic C₁-C₃₀ monovalent hydrocarbon group which may optionally include a heteroatom,
R₁₂ may be a linear, branched, or cyclic C₁-C₃₀ monovalent hydrocarbon group, which may optionally include a heteroatom, or *-M₁₂(R₁₃)ₘ(OR₁₄)₍₃₋ₘ₎,
n may be an integer from 1 to 4,
M₁₂ may be indium (In), tin (Sn), antimony (Sb), tellurium (Te), thallium (Tl), lead (Pb), bismuth (Bi), silver (Ag), or polonium (Po),
R₁₃ and R₁₄ may each independently be a linear, branched, or cyclic C₁-C₃₀ monovalent hydrocarbon group which may optionally include a heteroatom, m may be an integer from 0 to 3,
L₂₁ to L₂₃ may each independently be a single bond, O, S, C(═O), C(═O)O, OC(═O), C(═O)NH, NHC(═O), or a linear, branched, or cyclic C₁-C₃₀ divalent hydrocarbon group which may optionally include a heteroatom,
a21 to a23 may each independently be an integer from 1 to 4,
A₂₁ may be a cyclic C₁-C₃₀ hydrocarbon group including a heteroatom,
R₂₁ and R₂₂ may each independently be hydrogen, deuterium, halogen, or a linear, branched, or cyclic C₁-C₃₀ monovalent hydrocarbon group which may optionally include a heteroatom,
b22 may be an integer from 1 to 10,
p may be an integer from 1 to 5, and
* may be a binding site with an adjacent atom.

The organometallic compound may have a molecular weight of about 3,000 g/mol or less, specifically, about 100 g/mol or more to about 1,000 g/mol or less. The organometallic compound may not be a polymer and may be distinguished from a polymer in which one repeating unit of the polymer includes a metal.

In Formula 1, a bond between M₁₁ and R₁₁ may be an M₁₁-carbon single bond, and a bond between M₁₂ and R₁₃ may be an M₁₂-carbon single bond. In the organometallic compound, a bond between M₁₁ and R₁₂ and a bond between M₁₂ and R₁₄ may each be a bond through an oxygen atom, and in R₁₁ and R₁₃, carbon atoms included in R₁₁ and R₁₃ may be bonded to M₁₁ and M₁₂, respectively.

For example, in Formula 1, M₁₁ and M₁₂ may each be Sn, Sb, Te, Bi, or Ag.

Specifically, in Formula 1, M₁₁ and M₁₂ may each independently be Sn.

For example, in Formula 1, M₁₁ and M₁₂ may be identical to or different from each other.

Specifically, in Formula 1, M₁₁ and M₁₂ may be identical to each other.

For example, in Formula 1,
R₁₁ and R₁₃ may each independently be represented by *-(L₁₁)ₐ₁₁-X₁₁,
R₁₂ and R₁₄ may each independently be represented by *-(L₁₂)ₐ₁₂-X₁₂,
L₁₁ and L₁₂ may each independently be CRₐR_{b}, C═O, S═O, SO₂, PO₂, PO₃, or NO₂,
a11 and a12 may each independently be an integer from 0 to 3,
X₁₁ and X₁₂ may each independently be a substituted or unsubstituted C₁-C₃₀ alkyl group, a substituted or unsubstituted C₁-C₃₀ halogenated alkyl group, a substituted or unsubstituted C₁-C₃₀ alkoxy group, a substituted or unsubstituted C₁-C₃₀ alkylthio group, a substituted or unsubstituted C₁-C₃₀ halogenated alkoxy group, a substituted or unsubstituted C₁-C₃₀ halogenated alkylthio group, a substituted or unsubstituted C₃-C₃₀ cycloalkyl group, a substituted or unsubstituted C₃-C₃₀ cycloalkoxy group, a substituted or unsubstituted C₃-C₃₀ cycloalkylthio group, a substituted or unsubstituted C₃-C₃₀ heterocycloalkyl group, a substituted or unsubstituted C₃-C₃₀ heterocycloalkoxy group, a substituted or unsubstituted C₃-C₃₀ heterocycloalkylthio group, a substituted or unsubstituted C₂-C₃₀ alkenyl group, a substituted or unsubstituted C₂-C₃₀ alkenyloxy group, a substituted or unsubstituted C₂-C₃₀ alkenylthio group, a substituted or unsubstituted C₃-C₃₀ cycloalkenyl group, a substituted or unsubstituted C₃-C₃₀ cycloalkenyloxy group, a substituted or unsubstituted C₃-C₃₀ cycloalkenylthio group, a substituted or unsubstituted C₃-C₃₀ heterocycloalkenyl group, a substituted or unsubstituted C₃-C₃₀ heterocycloalkenyloxy group, a substituted or unsubstituted C₃-C₃₀ heterocycloalkenylthio group, a substituted or unsubstituted C₂-C₃₀ alkynyl group, a substituted or unsubstituted C₂-C₃₀ alkynyloxy group, a substituted or unsubstituted C₂-C₃₀ alkynylthio group, a substituted or unsubstituted C₆-C₃₀ aryl group, a substituted or unsubstituted C₆-C₃₀ aryloxy group, a substituted or unsubstituted C₆-C₃₀ arylthio group, a substituted or unsubstituted C₁-C₃₀ heteroaryl group, a substituted or unsubstituted C₁-C₃₀ heteroaryloxy group, or a substituted or unsubstituted C₁-C₃₀ heteroarylthio group, Ra and R_{b} may each independently be hydrogen, deuterium, a hydroxyl group, a cyano group, a nitro group, a substituted or unsubstituted C₁-C₃₀ alkyl group, a substituted or unsubstituted C₁-C₃₀ alkoxy group, a substituted or unsubstituted C₁-C₃₀ alkylthio group, a substituted or unsubstituted C₃-C₃₀ cycloalkyl group, a substituted or unsubstituted C₃-C₃₀ cycloalkoxy group, or a substituted or unsubstituted C₃-C₃₀ cycloalkylthio group, and
* may be a binding site with an adjacent atom.

In an embodiment, L₁₁ may be CRₐR_{b} or C═O, and L₁₂ may be C═O, S═O, SO₂, PO₂, PO₃, or NO₂.

In an embodiment, X₁₁ and X₁₂ may each independently be a substituted or unsubstituted C₁-C₃₀ alkyl group, a substituted or unsubstituted C₁-C₃₀ alkoxy group, a substituted or unsubstituted C₆-C₃₀ aryl group, a C₆-C₃₀ aryloxy group, a substituted or unsubstituted C₁-C₃₀ heteroaryl group, or a substituted or unsubstituted C₁-C₃₀ heteroaryloxy group.

In an embodiment, X₁₁ and X₁₂ may each independently be:
a C₁-C₂₀ alkyl group unsubstituted or substituted with at least one of deuterium, halogen, a hydroxy group, a C₁-C₆ alkyl group, a C₁-C₆ halogenated alkyl group, a C₁-C₆ alkoxy group, a C₁-C₆ halogenated alkoxy group, a C₁-C₆ halogenated alkylthio group, a C₃-C₆ cycloalkyl group, a C₃-C₆ cycloalkoxy group, a C₃-C₆ cycloalkylthio group, and a C₆-C₁₀ aryl group; or
a C₆-C₂₀ aryl group unsubstituted or substituted with at least one of deuterium, halogen, a hydroxy group, a C₁-C₆ alkyl group, a C₁-C₆ halogenated alkyl group, a C₁-C₆ alkoxy group, a C₁-C₆ halogenated alkoxy group, a C₁-C₆ halogenated alkylthio group, a C₃-C₆ cycloalkyl group, a C₃-C₆ cycloalkoxy group, a C₃-C₆ cycloalkylthio group, and a C₆-C₁₀ aryl group.

In an embodiment,
L₁₁ may be CRₐR_{b} or C═O,
L₁₂ may be C═O, S═O, SO₂, PO₂, PO₃, or NO₂,
a11 and a12 may be each independently 0 or 1, and
X₁₁ and X₁₂ may each independently be:
a C₁-C₂₀ alkyl group unsubstituted or substituted with at least one of deuterium, halogen, a hydroxy group, a C₁-C₆ alkyl group, a C₁-C₆ halogenated alkyl group, a C₁-C₆ alkoxy group, a C₁-C₆ halogenated alkoxy group, a C₁-C₆ halogenated alkylthio group, a C₅-C₆ cycloalkyl group, a C₅-C₆ cycloalkoxy group, a C₃-C₆ cycloalkylthio group, and a C₆-C₁₀ aryl group; or
a C₆-C₂₀ aryl group unsubstituted or substituted with at least one of deuterium, halogen, a hydroxy group, a C₁-C₆ alkyl group, a C₁-C₆ halogenated alkyl group, a C₁-C₆ alkoxy group, a C₁-C₆ halogenated alkoxy group, a C₁-C₆ halogenated alkylthio group, a C₃-C₆ cycloalkyl group, a C₃-C₆ cycloalkoxy group, a C₃-C₆ cycloalkylthio group, and a C₆-C₁₀ aryl group.

Specifically, the organometallic compound may be represented by any one of Formulas 1-1 to 1-16 below:

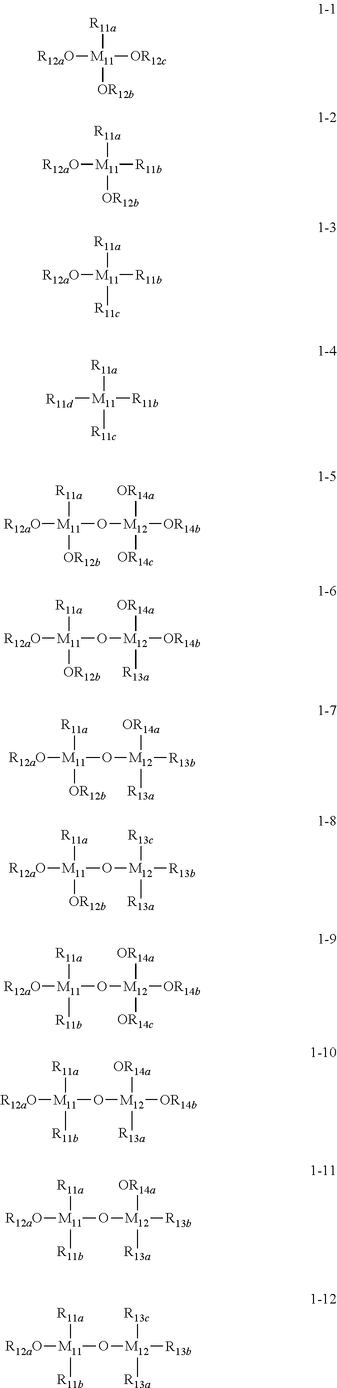

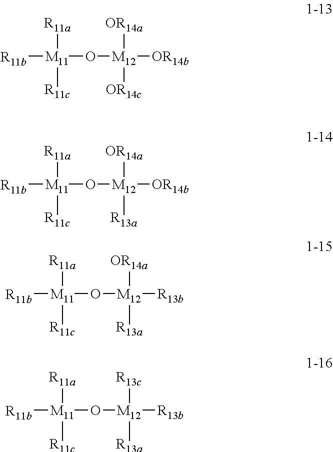

In Formulas 1-1 to 1-16,
for each of M₁₁ and M₁₂, the definition in Formula 1 is referred to,
for each of R₁₁ₐ to Rid, the definition of R₁₁ in Formula 1 is referred to,
for each of R₁₂ₐ to R_{12c}, the definition of R₁₂ in Formula 1 is referred to,
for each of R₁₃ₐ to R_{13c}, the definition of R₁₃ in Formula 1 is referred to, and
for each of R₁₄ₐ to R_{14c}, the definition of R₁₄ in Formula 1 is referred to.

More specifically, the organometallic compound may be represented by any one of Formulas 1-1 to 1-4 below.

In particular, the organometallic compound may be selected from Group I:

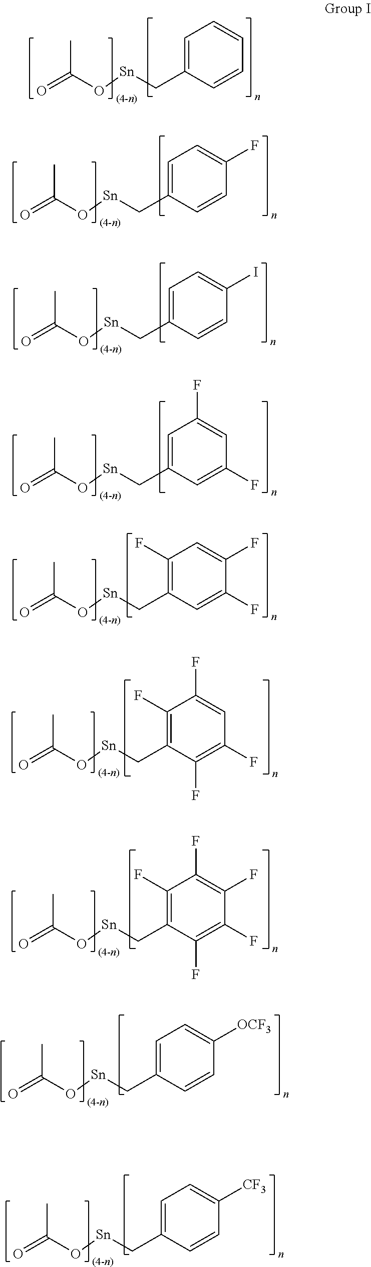

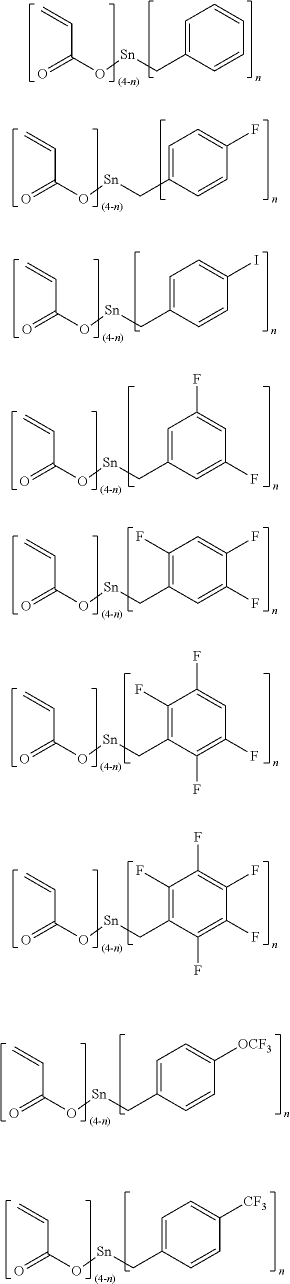

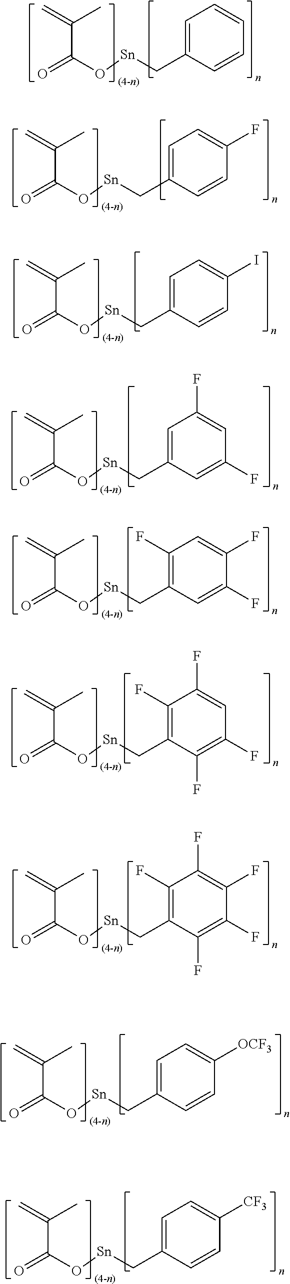

In Group I, n may be an integer from 1 to 4.

For example, in Group I, n may be 2.

The polymer may substantially not include a repeating unit of which a structure is changed by an acid. Here, the repeating unit of which a structure is changed by an acid may refer to a repeating unit including an acid labile group. The acid labile group may refer to an ester group having a tertiary acyclic alkyl carbon, an ester group having a tertiary alicyclic carbon, cyclic acetal, or the like. The acid labile group may be released from a polymer by an acid and may serve to make the polymer more readily soluble in a developing solution, such as an aqueous tetramethylammonium hydroxide (TMAH) solution.

For example, in Formula 2, L₂₁ to L₂₃ may each independently be a single bond, O, S, C(═O), C(═O)O, OC(═O), C(═O)NH, NHC(═O), a substituted or unsubstituted C₁-C₃₀ alkylene group, a substituted or unsubstituted C₃-C₃₀ cycloalkylene group, a substituted or unsubstituted C₁-C₃₀ heterocycloalkylene group, a substituted or unsubstituted phenylene group, a substituted or unsubstituted naphthylene group, or any combination thereof.

Specifically, in Formula 2, a21 to a23 may each independently be an integer from 1 to 3.

In Formula 2, A₂₁ may include a lone-pair electron pair.

Specifically, A₂₁ may include an oxygen atom, a sulfur atom, a nitrogen atom, a phosphorus atom, or any combination thereof as a heteroatom.

More specifically, A₂₁ may include an oxygen atom, a sulfur atom, a nitrogen atom, a phosphorus atom, S═O, P═O, C═O, or any combination thereof as a partial structure.

Specifically, in Formula 2, A₂₁ may be a C₃-C₂₀ heterocycloalkyl group including an oxygen atom, a sulfur atom, a nitrogen atom, or any combination thereof, a C₃-C₂₀ heterocycloalkenyl group including an oxygen atom, a sulfur atom, a nitrogen atom, or any combination thereof, a pyrrole group, a furan group, a thiophene group, an imidazole group, an oxazole group, a thiazole group, a pyridine group, a pyrazine group, a triazine group, a quinoline group, an isoquinoline group, a benzoquinoline group, a quinoxaline group, a quinazoline group, a cinnoline group, a phenanthroline group, a phenanthridine group, an indole group, a benzofuran group, a benzothiophene group, a benzimidazole group, a benzooxazole group, a benzothiazole group, a carbazole group, a dibenzofuran group, or a dibenzothiophene group.

More specifically, in Formula 2, A₂₁ may be a C₃-C₁₀ heterocycloalkyl group including an oxygen atom, a nitrogen atom, or any combination thereof, a C₃-C₁₀ heterocycloalkyl group including an oxygen atom, a nitrogen atom, or any combination thereof, a pyrrole group, an imidazole group, an oxazole group, a pyridine group, a pyrazine group, a triazine group, a quinoline group, an isoquinoline group, a benzoquinoline group, a quinoxaline group, a quinazoline group, a cinnoline group, a phenanthroline group, a phenanthridine group, an indole group, a benzimidazole group, a benzoxazole group, or a carbazole group.

More specifically, in Formula 2, A₂₁ may be a C₃-C₁₀ heterocycloalkyl group including a nitrogen atom, a C₃-C₁₀ heterocycloalkenyl group including a nitrogen atom, a pyrrole group, an imidazole group, a pyridine group, a pyrazine group, a triazine group, a quinoline group, an isoquinoline group, a benzoquinoline group, a quinoxaline group, a quinazoline group, a cinnoline group, a phenanthroline group, a phenanthridine group, an indole group, a benzimidazole group, or a carbazole group.

In particular, in Formula 2, A₂₁ may be a C₃-C₁₀ heterocycloalkyl group including a nitrogen atom, a C₃-C₁₀ heterocycloalkenyl group including a nitrogen atom, a pyridine group, a pyrazine group, a triazine group, a quinoline group, an isoquinoline group, a benzoquinoline group, a quinoxaline group, or a quinazoline group.

Specifically, in Formula 2, R₂₁ and R₂₂ may each independently be hydrogen, deuterium, halogen, a C₁-C₂₀ alkyl group, a C₁-C₂₀ halogenated alkyl group, a C₁-C₂₀ alkoxy group, a C₅-C₂₀ cycloalkyl group, a C₃-C₂₀ cycloalkyl group, a C₃-C₂₀ cycloalkoxy group, or a C₆-C₂₀ aryl group.

More specifically, in Formula 2, R₂₁ may be hydrogen, deuterium, halogen, CH₃, CH₂F, CHF₂, CF₃, CH₂CH₃, CHFCH₃, CHFCH₂F, CHFCHF₂, CHFCF₃, CF₂CH₃, CF₂CH₂F, CF₂CHF₂, or CF₂CF₃.

Specifically, in Formula 2, p may be an integer from 1 to 3.

More specifically, in Formula 2, p may be 1.

In an embodiment, the repeating unit represented by Formula 2 may be selected from Group II below:

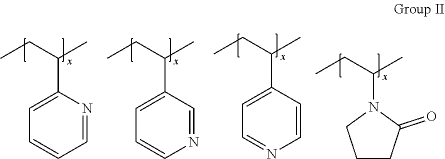

In an embodiment, the polymer may include (or consist of) the repeating unit represented by Formula 2.

In another embodiment, the polymer may be a copolymer including the repeating unit represented by Formula 2, for example, a block copolymer or a random copolymer.

In another embodiment, the polymer may further include a repeating unit represented by Formula 4 below:

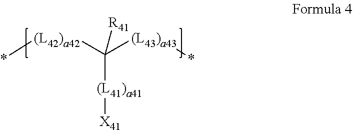

In Formula 4,
R₄₁ may be hydrogen, deuterium, halogen, or a linear, branched, or cyclic C₁-C₃₀ monovalent hydrocarbon group which may optionally include a heteroatom,
L₄₁ to L₄₃ may each independently be: a single bond; O; S; C(═O); C(═O)O; OC(═O); C(═O)NH; NHC(═O); a linear, branched, or cyclic C₁-C₃₀ divalent hydrocarbon group, which may optionally include a heteroatom; or any combination thereof,
a41 to a43 may each independently be an integer from 1 to 6, X₄₁ may be a non-acid labile group, and
* may be a bonding site with an adjacent atom.

Specifically, for R₄₁ in Formula 4, the description of R₂₁ in Formula 2 is referred to.

Specifically, for L₄₁ to L₄₃ in Formula 4, the description of L₂₁ in Formula 2 is referred to.

For example, in Formula 4, X₄₁ may be: hydrogen; or a linear, branched, or cyclic C₁-C₂₀ monovalent hydrocarbon group including at least one polar moiety selected from a hydroxy group, halogen, a cyano group, a carbonyl group, a carboxyl group, O, S, C(═O), C(═O)O, OC(═O), S(═O)O, OS(═O), a lactone ring, a sultone ring, and a carboxylic anhydride moiety.

Specifically, in Formula 4, X₄₁ may be represented by any one of Formulas 5-1 to 5-5 below:

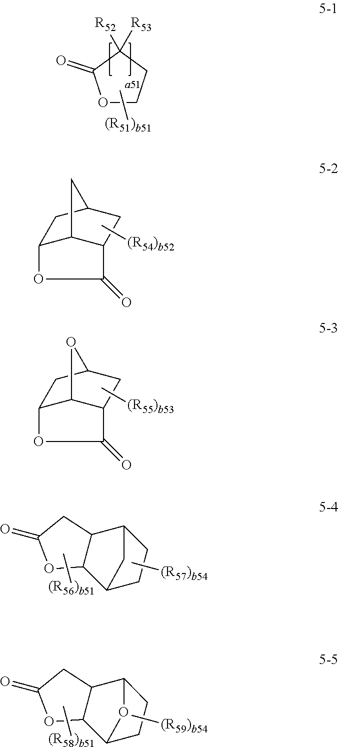

In Formulas 5-1 to 5-5,
a51 may be 1 or 2,
R₅₁ to R₅₉ may each independently be a bonding site with an adjacent atom, hydrogen, a hydroxy group, a halogen, a cyano group, a C₁-C₆ alkyl group, a C₁-C₆ halogenated alkyl group, a C₁-C₆ alkoxy group, a C₃-C₆ cycloalkyl group, a C₃-C₆ cycloalkoxy group, or a C₆-C₁₀ aryl group,
one of R₅₁ to R₅₃, one of R₅₄, one of R₅₅, one of R₅₆ and R₅₇, and one of R₅₈ and R₅₉ may be a binding site with an adjacent atom,
b51 may be an integer from 1 to 4,
b52 may be an integer from 1 to 10,
b53 and b54 may each independently be an integer from 1 to 8, and
b55 may be an integer from 1 to 6.

In an embodiment, the repeating unit represented by Formula 4 may be represented by any one of Formula 4-1 and Formula 4-2 below:

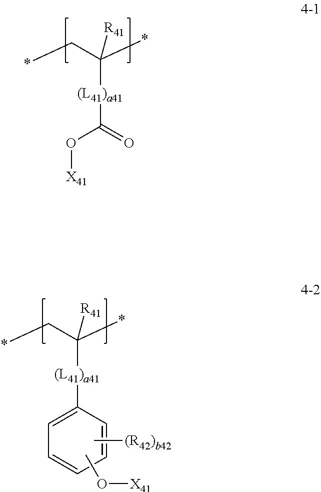

In Formula 4-1 and Formula 4-2,
the definitions of L₄₁ and X₄₁ may each be the same as those in Formula 4,
a41 may be an integer from 1 to 4,
R₄₂ may be hydrogen, or a linear, branched, or cyclic C₁-C₂₀ monovalent hydrocarbon group,
b42 may be an integer from 1 to 4, and
each * may be a bonding site with an adjacent atom.

In an embodiment, the polymer may include (or consist of) the repeating unit represented by Formula 2 and the repeating unit represented by Formula 4. Specifically, the polymer may include about 1 mol % to about 90 mol % of the repeating unit represented by Formula 4 and about 10 mol % to about 99 mol % of the repeating unit represented by Formula 2. More specifically, the polymer may include about 10 mol % to about 80 mol % of the repeating unit represented by Formula 4 and about 20 mol % to about 90 mol % of the repeating unit represented by Formula 2.

The polymer may consist only of repeating units having the same structure or may include two or more different types of repeating units.

The polymer may have a weight average molecular weight Mw of about 1,000 to about 500,000, and specifically, about 2,000 or more, about 3,000 or more, about 200,000 or less, about 100,000 or less, about 20,000 or less, or about 10,000 or less which is measured through gel permeation chromatography using a tetrahydrofuran solvent and polystyrene as standard materials.

A polydispersity index (PDI: Mw/Mn) of the polymer may be in a range of about 1.0 to about 6.0, specifically, about 1.0 to about 4.5. When the above-described range is satisfied, the dispersibility and/or compatibility of the polymer may be easy to control, and a possibility of foreign materials remaining on a pattern may be reduced, or the deterioration of a pattern profile may be minimized. Accordingly, the resist composition may be more suitable for forming a fine pattern.

Although not limited to a particular theory, in the organometallic compound, radicals may be formed by heat and/or high energy rays. Specifically, a radical may be formed from a metal-carbon bond of the organometallic compound, and the polymer may accept the radical to form a chemical bond. Due to the chemical bond, a crosslink may be formed between at least the organometallic compound and the polymer, and physical properties of the polymer, particularly, the solubility thereof in a developing solution, may be changed due to the chemical bond.

The physical properties of the polymer itself may be changed by an organometallic compound and/or high energy rays, and thus the resist composition may be used as a non-chemically amplified resist composition.

The polymer may have relatively high resistance to oxygen and/or moisture, and the physical properties thereof may be changed only by high energy rays, thereby providing a resist composition with improved storage stability and the like.

Since a newly formed chemical bond induces a change in physical properties of the polymer, the polymer may provide a resist composition capable of being patterned even with a small dose of high energy rays as compared with a system in which a polymer main chain is decomposed to induce a change in physical properties.

The polymer may be prepared through any suitable method and may be prepared, for example, by dissolving unsaturated bond-containing monomer(s) in an organic solvent, and then photopolymerizing and/or heat-polymerizing the unsaturated bond-containing monomer(s) in a radical initiator.

A structure (composition) of the polymer may be identified by performing Fourier transform infrared (FT-IR) analysis, nuclear magnetic resonance (NMR) analysis, fluorescence X-ray (XRF) analysis, mass spectrometry, ultraviolet (UV) analysis, single crystal X-ray structure analysis, powder X-ray diffraction (PXRD) analysis, liquid chromatography (LC) analysis, size exclusion chromatography (SEC) analysis, thermal analysis, or the like. A detailed identification method is as described in Examples.

The solubility of the resist composition in a developing solution may be changed by exposure to high energy rays. The resist composition may be a negative-type resist composition in which an unexposed portion of a resist film is dissolved and removed to form a negative-type resist pattern.

In addition, a sensitive resist composition according to an embodiment may be for an alkali developing process in which an alkali developing solution is used for a developing process when a resist pattern is formed and may also be for a solvent developing process in which an organic solvent-containing developing solution (hereinafter referred to as an organic developing solution) is used for the developing process.

Since the resist composition is non-chemically amplified, the resist composition may not substantially include a photoacid generator.

Since the physical properties of the polymer is changed by exposure to light, the resist composition may not substantially include a compound having a molecular weight of about 1,000 or more other than the polymer.

In the resist composition, the organometallic compound may be included in a range of about 10 parts by weight to about 1,000 parts by weight, specifically, about 20 parts by weight to about 500 parts by weight, with respect to about 100 parts by weight of the polymer. When the above range is satisfied, a chemical bond between the organometallic compound and the polymer may be sufficiently formed to provide a resist composition with improved sensitivity and/or resolution.

Since the polymer is as described above, an organic solvent and any components contained as necessary will be described below. In addition, one type of polymer may be used in the resist composition, or two or more different types of polymers may be used in combination.

### <Organic Solvent>

The resist composition may further include an organic solvent. An organic solvent included in the resist composition is not particularly limited as long as the organic solvent may dissolve or disperse the polymer and any components contained as needed. As the organic solvent, one type of an organic solvent may be used, or two or more different types of organic solvents may be used in combination. In addition, a mixed solvent in which water and an organic solvent are mixed may be used.

Examples of the organic solvent may include, for example, an alcohol-based solvent, an ether-based solvent, a ketone-based solvent, an amide-based solvent, an ester-based solvent, a sulfoxide-based solvent, a hydrocarbon-based solvent, and the like.

More specifically, examples of the alcohol-based solvent may include a monoalcohol-based solvent such as methanol, ethanol, n-propanol, isopropanol, 1-methoxy-2-propanol, 1-ethoxy-2-propanol, n-butanol, isobutanol, sec-butanol, tert-butanol, n-pentanol, isopentanol, 2-methylbutanol, sec-pentanol, tert-pentanol, 3-methoxybutanol, 3-methyl-3-methoxybutanol, n-hexanol, 2-methylpentanol, sec-hexanol, 2-ethylbutanol, sec-heptanol, 3-heptanol, n-octanol, 2-ethylhexanol, sec-octanol, n-nonylalcohol, 2,6-dimethyl-4-heptanol, n-decanol, sec-undecyl alcohol, trimethylnonyl alcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol, or diacetone alcohol, a polyhydric alcohol-based solvent such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, or tripropylene glycol, and a polyhydric alcohol-containing ether-based solvent such as ethylene glycol monomethyl ether, ethylene glycol monoethyl ether, ethylene glycol monopropyl ether, ethylene glycol monobutyl ether ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, propylene glycol monomethyl ether, propylene glycol monoethyl ether, propylene glycol monopropyl ether, propylene glycol monobutyl ether, dipropylene glycol monomethyl ether, dipropylene glycol monoethyl ether, or dipropylene glycol monopropyl ether.

Examples of the ether-based solvent may include a dialkyl ether-based solvent such as diethyl ether, dipropyl ether, dibutyl ether, diethylene glycol dimethyl ether, or propylene glycol dimethyl ether, or a cyclic ether-based solvent such as tetrahydrofuran or tetrahydropyran, and an aromatic ring-containing ether-based solvent such as diphenyl ether or anisole.

Examples of the ketone-based solvent may include a chain ketone-based solvent such as acetone, methyl ethyl ketone, methyl n-propyl ketone, methyl n-butyl ketone, diethyl ketone, methyl iso-butyl ketone, 2-heptanone, ethyl-n-butyl ketone, methyl-n-hexyl ketone, diisobutyl ketone, or trimethylnonanone, a cyclic ketone-based solvent such as cyclopentanone, cyclohexanone, cycloheptanone, cyclooctanone, or methylcyclohexanone, 2,4-pentanedione, acetonyl acetone, and acetophenone.

Examples of the amide-based solvent may include a cyclic amide-based solvent such as N,N′-dimethylimidazolidinone or N-methyl-2-pyrrolidone, and a chain amide-based solvent such as N-methylformamide, N,N-dimethylformamide, N,N-diethylformamide, acetamide, N-methylacetamide, N,N-dimethylacetamide, or N-methylpropionamide.

Examples of the ester-based solvent may include an acetate ester-based solvent such as methyl acetate, ethyl acetate, n-propyl acetate, isopropyl acetate, n-butyl acetate (nBA), isobutyl acetate, sec-butyl acetate, t-butyl acetate, n-pentyl acetate, isopentyl acetate sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, or n-nonyl acetate, a polyhydric alcohol-containing ether carboxylate-based solvent such as ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, or dipropylene glycol monoethyl ether acetate, a lactone-based solvent such as γ-butyrolactone or δ-valerolactone, a carbonate-based solvent such as dimethyl carbonate, diethyl carbonate, ethylene carbonate, or propylene carbonate, a lactate ester-based solvent such as methyl lactate, ethyl lactate, n-butyl lactate, or n-amyl lactate, glycoldiacetate, methoxytriglycol acetate, ethyl propionate, n-butyl propionate, isoamyl propionate, diethyloxalate, di-n-butyloxalate, methyl acetoacetate, ethyl acetoacetate, diethyl malonate, dimethyl phthalate, and diethyl phthalate.

Examples of the sulfoxide-based solvent may include dimethyl sulfoxide, diethyl sulfoxide, and the like.

Examples of the hydrocarbon-based solvent may include an aliphatic hydrocarbon-based solvent such as n-pentane, isopentane, n-hexane, isohexane, n-heptane, isoheptane, 2,2,4-trimethylpentane, n-octane, isooctane, cyclohexane, or methylcyclohexane, and an aromatic hydrocarbon-based solvent such as benzene, toluene, xylene, mesitylene, ethylbenzene, trimethylbenzene, methylethylbenzene, n-propylbenzene, isopropylbenzene, diethylbenzene, isobutylbenzene, triethylbenzene, diisopropylbenzene, or n-amylnaphthalene.

Specifically, the organic solvent may be selected from an alcohol-based solvent, an amide-based solvent, an ester-based solvent, a sulfoxide-based solvent, and any combination thereof. More specifically, the organic solvent may be selected from propylene glycol monomethyl ether, propylene glycol monoethyl ether, propylene glycol monomethyl ether acetate, N-methyl-2-pyrrolidone, N,N-dimethylacetamide, ethyl lactate, dimethyl sulfoxide, and any combination thereof.

The organic solvent may be used in a range of about 200 parts by weight to about 5,000 parts by weight, specifically, about 400 parts by weight to about 3,000 parts by weight, with respect to about 100 parts by weight of the polymer.

### <Any Components>

The resist composition may further include a surfactant, a crosslinking agent, a leveling agent, a colorant, or any combination thereof as necessary.

The resist composition may further include a surfactant to improve coatability, developability, and the like. A specific example of the surfactant may include, for example, a nonionic surfactant such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, or polyethylene glycol distearate. As the surfactant, a commercially available product or a synthetic product may be used. Examples of the commercially available product of the surfactant may include KP341 (manufactured by Shin-Etsu Chemical Co., Ltd.), Polyflow No. 75 and Polyflow No. 75 (manufactured by Kyoeisha Chemical Co., LTD.), Eftop EF301, Eftop 303, and Eftop 352 (manufactured by Mitsubishi Materials Electronic Chemicals Co., Ltd.), MEGAFACE™ F171, MEGAFACE™ F173, R-40, R-41, and R-43 (products manufactured by DIC Corporation), Fluorad™ FC430 and FLUORAD™ FC431 (manufactured by Sumitomo 3M, Ltd.), ASAHI GUARD™ AG710 (manufactured by AGC Seimi Chemical Co., Ltd.), and SURFLON™ S-382, SURFLON™ SC-101, SURFLON™ SC-102, SURFLON™ SC-103, SURFLON™ SC-104, SURFLON™ SC-105, and SURFLON™ SC-106 (manufactured by AGC Seimi Chemical Co., Ltd.).

The surfactant may be included in a range of about 0 parts by weight to about 20 parts by weight with respect to about 100 parts by weight of the polymer. As the surfactant, one type of a surfactant may be used, or two or more different types of surfactants may be mixed and used.

A method of preparing the resist composition is not particularly limited, and for example, a method of mixing a polymer and any components added as needed in an organic solvent may be used. A temperature or time during mixing is not particularly limited. If necessary, filtration may be performed after mixing.

### [Resist Composition and Monomer Included]

A resist composition according to embodiments may include:
an organometallic compound represented by Formula 1 below; and
a monomer represented by Formula 20 below:

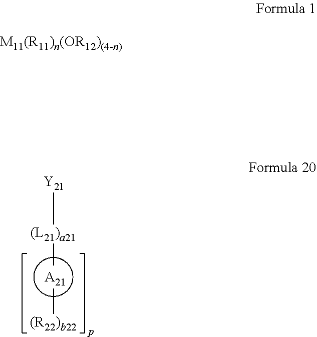

In Formula 1 and Formula 20,
M₁₁ may be indium (In), tin (Sn), antimony (Sb), tellurium (Te), thallium (Tl), lead (Pb), bismuth (Bi), silver (Ag), or polonium (Po),
R₁₁ may be a C₁-C₃₀ linear, branched, or cyclic monovalent hydrocarbon group which may optionally include a heteroatom,
R₁₂ may be a linear, branched, or cyclic C₁-C₃₀ monovalent hydrocarbon group, which may optionally include a heteroatom, or *-M₁₂(R₁₃)ₘ(OR₁₄)₍₃₋ₘ₎, n may be an integer from 1 to 4,
M₁₂ may be indium (In), tin (Sn), antimony (Sb), tellurium (Te), thallium (Tl), lead (Pb), bismuth (Bi), silver (Ag), or polonium (Po),
R₁₃ and R₁₄ may each independently be a linear, branched, or cyclic C₁-C₃₀ monovalent hydrocarbon group which may optionally include a heteroatom,
m may be an integer from 0 to 3,
Y₂₁ may be a polymerizable group,
L₂₁ may be: a single bond; O; S; C(═O); C(═O)O; OC(═O); C(═O)NH; NHC(═O); or a linear, branched, or cyclic C₁-C₃₀ divalent hydrocarbon group which may optionally include a heteroatom,
a21 may be an integer from 1 to 4,
A₂₁ may be a cyclic C₁-C₃₀ hydrocarbon group including a heteroatom, R₂₂ may be hydrogen, deuterium, halogen, or a linear, branched, or cyclic C₁-C₃₀ monovalent hydrocarbon group which may optionally include a heteroatom,
b22 may be an integer from 1 to 10, and
p may be an integer from 1 to 5.

For example, in Formula 20, Y₂₁ may include a vinyl group, an acrylate group, a methacrylate group, an oxirane group, an epoxy group, an oxetane group, a thiol group, or any combination thereof as a partial structure.

Specifically, in Formula 20, Y₂₁ may include a vinyl group, an acrylate group, a methacrylate group, or any combination thereof as a partial structure.

In an embodiment, the monomer represented by Formula 20 may be selected from Group III below:

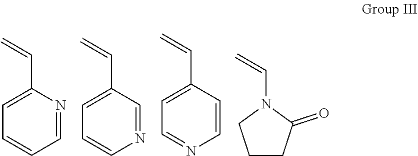

The resist composition including the monomer is the same as the resist composition including the above-described polymer except that the monomer is included instead of the polymer. For a description of the resist composition including the monomer, the resist composition including the polymer is referred to.

### [Method of Forming Pattern]

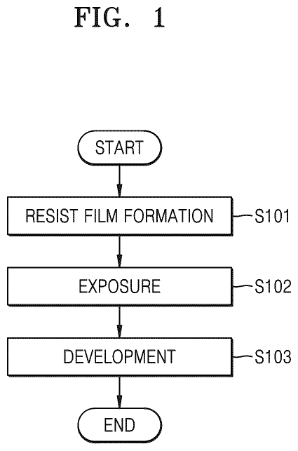

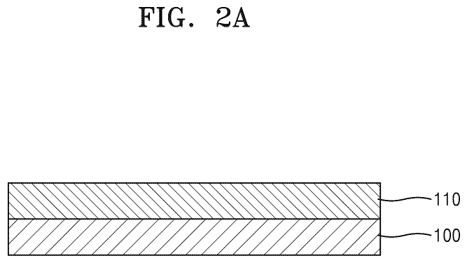

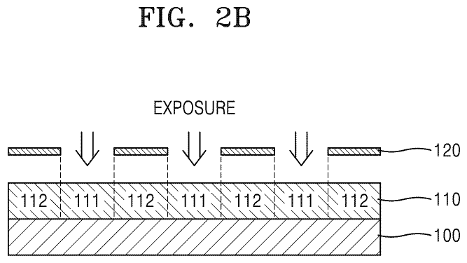

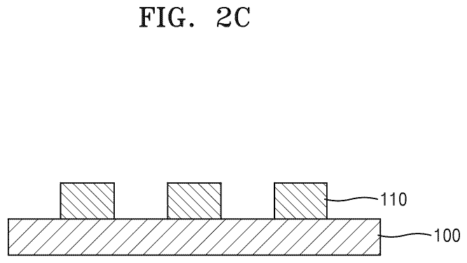

Hereinafter, a method of forming a pattern according to embodiments will be described in more detail with reference to FIGS. 1 and 2A to 2C. FIG. 1 is a flowchart illustrating the method of forming a pattern according to embodiments, and FIG. 2 shows side cross-sectional views illustrating the method of forming a pattern according to embodiments. Hereinafter, an example of the method of forming a pattern using a negative resist composition will be described in detail, but one or more embodiments are not limited thereto.

Referring to FIG. 1, the method of forming a pattern may include operation S101 of applying a resist composition to form a resist film, operation S102 of exposing at least a portion of the resist film to high energy rays, and operation S103 of developing the exposed resist film using a developing solution. Such operations may be omitted if necessary, or may be performed in a different order.

First, a substrate 100 may be prepared. The substrate 100 may include, for example, a semiconductor substrate such as a silicon substrate or a germanium substrate, glass, quartz, ceramic, or copper. In some embodiments, the substrate 100 may include a Group III-V compound such as GaP, GaAs, GaSb, or the like.

A resist composition may be applied to a desired thickness on the substrate 100, specifically, through a coating method, to form a resist film 110. If necessary, heating (referred to as pre-bake (PB) or post-annealing bake (PAB)) may be performed to remove an organic solvent remaining in the resist film 110. Alternatively, the resist film 110 may be heated to generate radicals, and then the radicals may be chemically bonded through exposure to form a crosslink.

As the coating method, spin coating, dipping, roller coating, or other general coating methods may be used. Among the coating methods, in particular, spin coating may be used, and the viscosity, concentration, and/or spin speed of the resist composition may be adjusted to form the resist film 110 having a desired thickness. Specifically, the resist film 110 may have a thickness of about 10 nm to about 300 nm. More specifically, the resist film 110 may have a thickness of about 15 nm to about 200 nm.

A lower limit of a temperature of the PAB may be 60° C. or more, specifically, 80° C. or more. In addition, the upper limit of the temperature of the PAB may be 200° C. or less, specifically, 180° C. or less. A lower limit of a time of the PAB may be 5 seconds or more, specifically, 10 seconds or more. An upper limit of the time of the PAB may be 600 seconds or less, specifically, 300 seconds or less.

Before the applying of the resist composition on the substrate 100, an etching target film (not shown) may be further formed on the substrate 100. The etching target film may refer to a layer on which an image is transferred from a resist pattern and converted into a certain pattern. In an embodiment, the etching target film may be formed to include, for example, an insulating material such as silicon oxide, silicon nitride, or silicon oxynitride. In some embodiments, the etching target film may be formed to include a conductive material such as a metal, metal nitride, metal silicide, or metal silicide nitride. In some embodiments, the etching target film may be formed to include a semiconductor material such as polysilicon.

In an embodiment, an antireflection film may be further formed on the substrate 100 to maximize the efficiency of a resist. The antireflection film may be an organic or inorganic antireflection film.

In an embodiment, a protective film may be further provided on the resist film 110 to reduce the influence of alkaline impurities or the like included during a process. When immersion exposure is performed, for example, a protective film for immersion may also be provided on the resist film 100 to avoid direct contact between an immersion medium and the resist film 110.

Next, at least a portion of the resist film 110 may be exposed to high energy rays. For example, high energy rays passing through a mask 120 may be irradiated onto at least a portion of the resist film 110. For this reason, the resist film 110 may have an exposed portion 111 and an unexposed portion 112.

Although not limited to a specific theory, radicals may be generated in the exposed portion 111 through exposure, and chemical bonds may be formed between the radicals so that the physical properties of a resist composition may be changed.

In some cases, the exposure may be performed by irradiating high energy rays through a mask with a certain pattern using a liquid such as water as a medium. Examples of the high energy rays may include electromagnetic waves such as UV rays, deep ultraviolet (DUV) rays, extreme ultraviolet (EUV) rays (with a wavelength of 13.5 nm), X-rays, and γ-rays, and charged particle beams such as electron beams (EBs) and α rays, and the like. Irradiating the high energy rays may be collectively referred to as “exposure.”

Examples of an exposure light source may include various light sources such as a light source that emits laser light in a UV region, such as a KrF excimer laser (with a wavelength of 248 nm), an ArF excimer laser (with a wavelength of 193 nm), or an F₂ excimer laser (with a wavelength of 157 nm), a light source that converts a wavelength of laser light from a solid-state laser light source (yttrium aluminum garnet (YAG) or semiconductor laser or the like) to emit harmonic laser light in a far UV or vacuum UV region, and a light source that irradiates EBs or EUV rays. During exposure, the exposure may be usually performed through a mask corresponding to a desired pattern, but when exposure light is an EB, the exposure may be performed through direct writing without using a mask.

Regarding an integral dose of high energy rays, for example, when EUV rays are used as the high energy rays, the integral dose may be 2,000 mJ/cm² or less, specifically, 500 mJ/cm² or less. In addition, when EBs are used as the high energy rays, the integral dose may be 5,000 μC/cm² or less, specifically, 1,000 μC/cm² or less.

In addition, post-exposure bake (PEB) may be performed after the exposure. A lower limit of a temperature of the PEB may be 50° C. or more, specifically, 80° C. or more. An upper limit of the temperature of the PEB may be 250° C. or less, specifically, 200° C. or less. A lower limit of a time of the PEB time may be 5 seconds or more, specifically, 10 seconds or more. An upper limit of the time of the PEB may be 600 seconds or less, specifically, 300 seconds or less.

Next, the exposed resist film 110 may be developed using a developing solution. The unexposed portion 112 may be washed away by the developing solution, and the exposed portion 111 may remain unwashed away by the developing solution.

Examples of the developing solution may include an alkaline developing solution and a developing solution including an organic solvent (hereinafter also referred to as “organic developing solution”). Examples of a developing method may include a dipping method, a puddle method, a spray method, a dynamic injection method, and the like. A developing temperature may be, for example, 5° C. or more and 60° C. or less, and a developing time may be, for example, 5 seconds or more and 300 seconds or less.

The alkaline developing solution may include, for example, an alkaline aqueous solution in which one or more alkaline compounds such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethyamine, ethyldimethylamine, triethanolamine, TMAH, pyrrole, piperidine, choline, 1,8-diazabicyclo[5.4.0]-7-undecene (DBU), and 1,5-diazabicyclo[4.3.0]-5-nonene (DBN) are dissolved. The alkali developing solution may further include a surfactant.

A lower limit of a content of the alkaline compound in the alkali developing solution may be 0.1 wt % or more, specifically, 0.5 wt % or more, and more specifically, 1 wt % or more. In addition, an upper limit of the content of the alkaline compound in the alkaline developing solution may be 20 wt % or less, specifically, 10 wt % or less, and more specifically, 5 wt % or less.

Examples of the organic solvent included in the organic developing solution may include the same organic solvents as those examples in the part of <Organic solvent> of [Resist composition]. Specifically, the organic developing solvent may include nBA, propylene glycol methyl ether (PGME), propylene glycol methyl ether acetate (PGMEA), γ-butyrolactone (GBL), isopropanol (IPA), or the like.

A lower limit of a content of the organic solvent in the organic developing solvent may be 80 wt % or more, specifically, 90 wt % or more, more specifically, 95 wt % or more, or particularly, 99 wt % or more.

The organic developing solvent may also include a surfactant. In addition, a trace amount of water may be included in the organic developing solvent. Furthermore, during development, the development may be stopped by substituting the organic developing solution with a solvent that is a different type therefrom.

The resist pattern after the development may be further cleaned. Ultrapure water, a rinse solution, or the like may be used as a cleaning solution. A rinse solution is not particularly limited as long as the rinse solution does not dissolve a resist pattern, and a solution including a general organic solvent may be used. For example, the rinse solution may be an alcohol-based solvent or an ester-based solvent. After the cleaning, the rinse solution remaining on the substrate 100 and the resist pattern may be removed. In addition, when the ultrapure water is used, water remaining on the substrate 100 and the resist pattern may be removed.

In addition, developing solutions may be used singly or in a combination of two or more.

After the resist pattern is formed as described above, a pattern interconnection substrate may be obtained through etching. The etching may be performed through a known method including dry etching using a plasma gas and wet etching using an alkaline solution, a copper (II) chloride solution, an iron (II) chloride solution, or the like.

After the resist pattern is formed, plating may be performed. The plating is not particularly limited, and examples thereof may include copper plating, solder plating, nickel plating, gold plating, and the like.

The resist pattern remaining after the etching may be peeled off with an organic solvent. One or more embodiments are not limited thereto, but examples of such an organic solvent may include PGMEA, PGME, ethyl lactate (EL), and the like. A peeling method is not particularly limited, but examples thereof may include an immersion method, a spray method, and the like. In addition, the pattern interconnection substrate on which the resist pattern is formed may be a multilayer interconnection substrate or may have small-diameter through-holes.

In an embodiment, the pattern interconnection substrate may be formed through a method of forming a resist pattern, depositing a metal in a vacuum, and then melting the resist pattern with a solution, that is, a lift-off method.

The disclosure will be described in more detail using the following Examples and Comparative Examples, but the technical scope of inventive concepts in the present disclosure is not limited only to the following Examples.

### Examples

P4VP (Mw=60 kDa) is poly(4-vinylpyridine) obtained from Sigma-Aldrich Co. LLC and is a polymer with Mw of about 60,000.

P4VP (Mw=6 kDa and PDI<2) is Ω-vinyl-terminated poly(4-vinylpyridine) obtained from Polymer Source Inc. and is a polymer with Mw of about 6,000 and PDI of less than of 1.2.

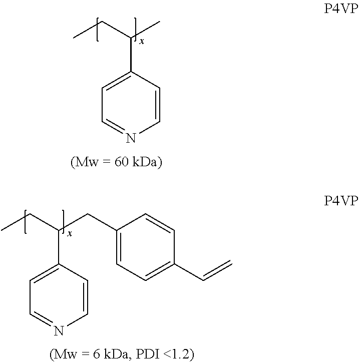

### Synthesis Example 1: Synthesis of Compound T1

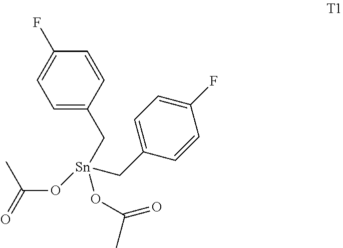 [SMILES: CC(=O)[O][Sn]([CH2]c1ccc(F)cc1)([CH2]c1ccc(F)cc1)[O]C(C)=O]

### (1) Synthesis of Di(4-Fluorobenzyl)Tin Dichloride (FB)

<di(4-fluorobenzyl)tin dichloride (FB)>

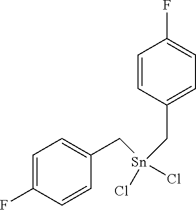 [SMILES: Fc1ccc([CH2][Sn]([Cl])([Cl])[CH2]c2ccc(F)cc2)cc1]

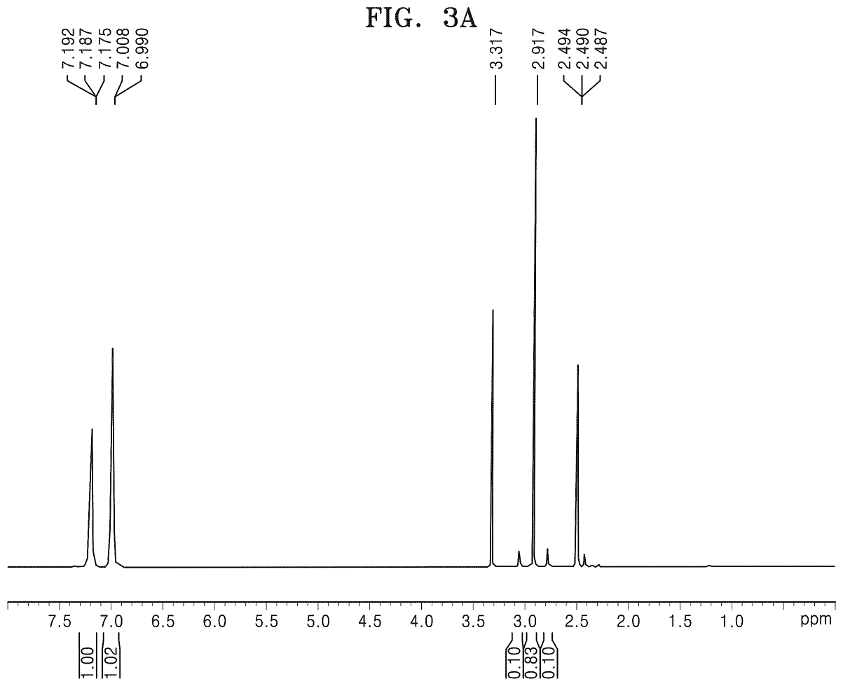

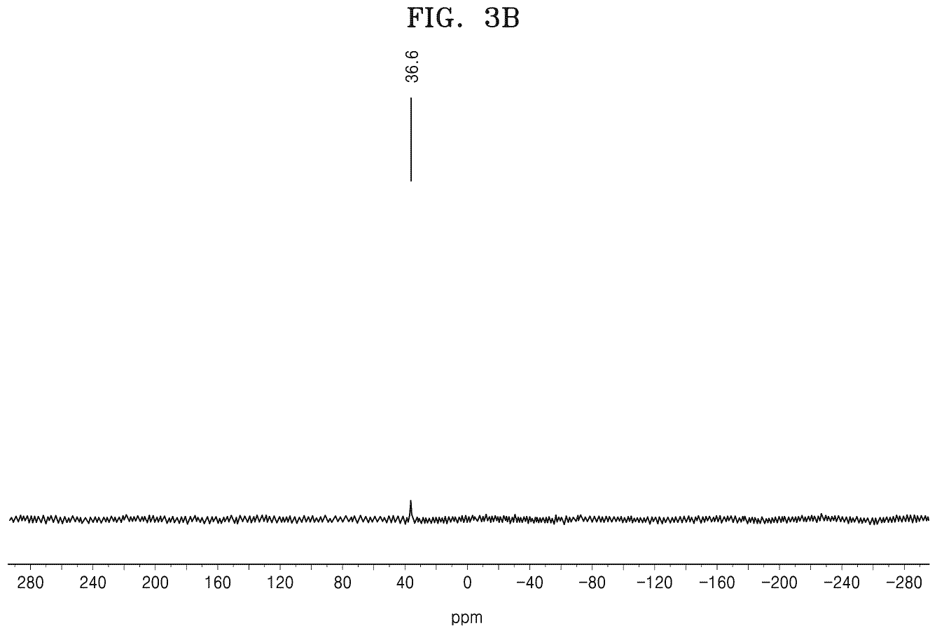

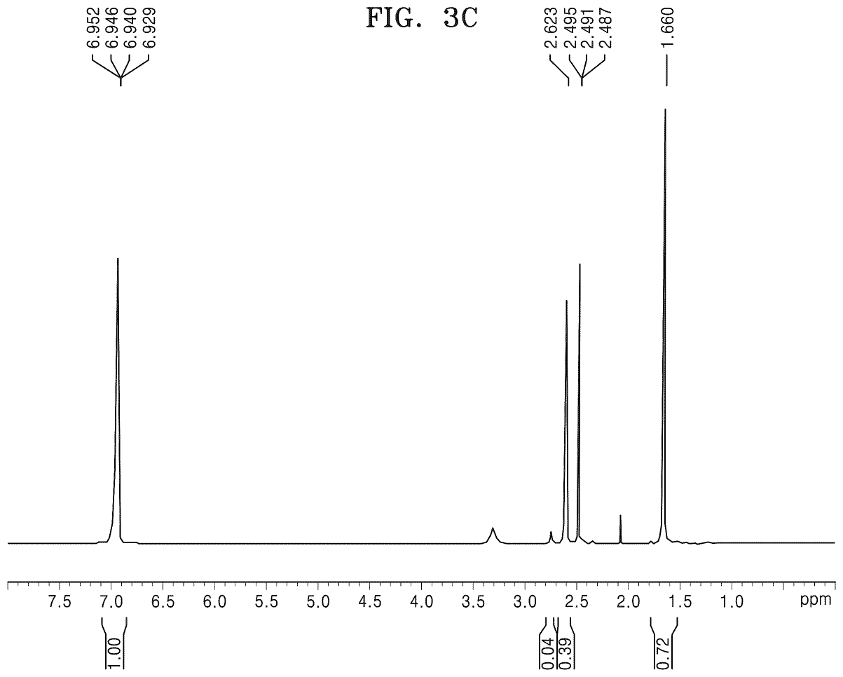

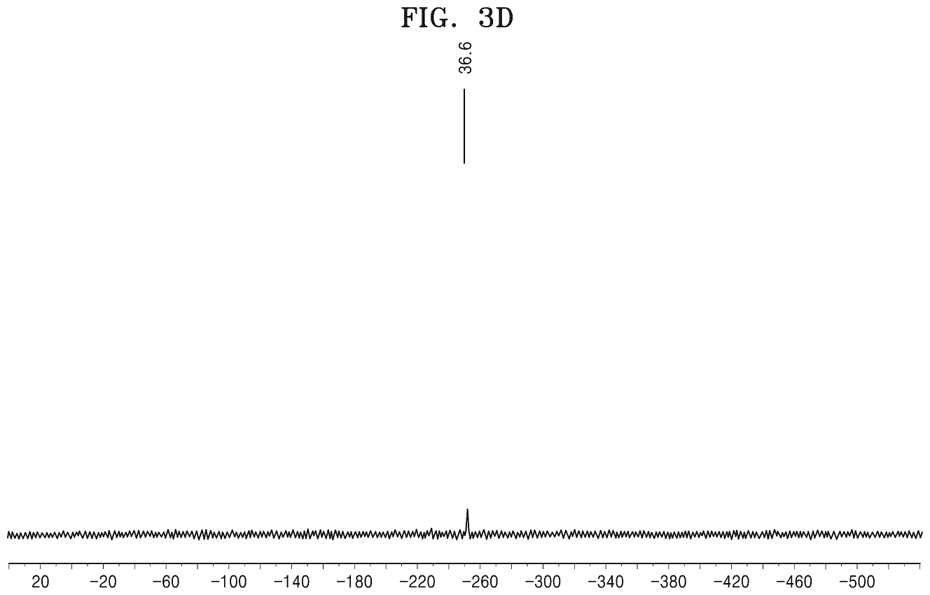

Tin powder (8.2 g, 69 mmol) and 120 ml of dry toluene were put into a 250 ml reaction flask and heated to a temperature of 90° C. Then, 0.82 g of pure water was added as a catalyst, and 4-fluorobenzyl chloride (10 g, 69 mmol) was added dropwise for 10 minutes. A reaction temperature was raised to 130° C., and then reflux heating was performed for 4 hours. After a reaction was complete, unreacted powder was removed through a filter and cooled to obtain white crystals. The obtained white crystals were washed with cold toluene and then dried at a temperature of 40° C. overnight to obtain 10.92 g of Compound FB (yield: 60%). Obtained Compound FB was analyzed using ¹H-NMR and ¹¹⁹Sn-NMR. Analysis results are shown in FIGS. 3A and 3B, respectively.

### (2) Synthesis of Di(4-Fluorobenzyl)Tin Dicarboxylate (T1)

<di(4-fluorobenzyl)tin dicarboxylate (acetate) (T1)>

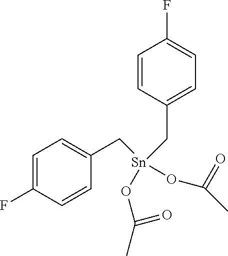 [SMILES: CC(=O)[O][Sn]([CH2]c1ccc(F)cc1)([CH2]c1ccc(F)cc1)[O]C(C)=O]

Di(4-fluorobenzyl)tin dichloride (0.5 g, 1.23 mmol) and 7 g of acetone were put into a 50 ml reaction flask in an ice bath. sodium acetate (0.2 g, 2.45 mmol) was added thereto. The resultant mixture was stirred overnight and filtered, and an obtained solid was dried to obtain 0.45 g of Compound T1 (yield: 65%). Obtained Compound T1 was analyzed using ¹H-NMR and ¹¹⁹Sn-NMR. Analysis results are shown in FIGS. 3C and 3D, respectively.

### Evaluation Example: Evaluation of Thin Film Development

### (1) Terminology

Eₜₕ means an exposure amount at a time point at which a thin film starts to be cured, and E₁ means an exposure amount at a saturation point at which a thickness of the thin film does not become thicker. A remaining film ratio is a value, which is obtained by dividing a thin film thickness at a saturation point by an initial thickness, is expressed as a percentage, and γ is a contrast curve and is a value calculated by Equation 1 below:

$$γ = {\vert log ( \frac{{E}_{th}}{{E}_{1}} ) \vert}^{- 1} \qquad Equation 1$$

### (2) Evaluation of Thin Film Phenomenon According to Light Source

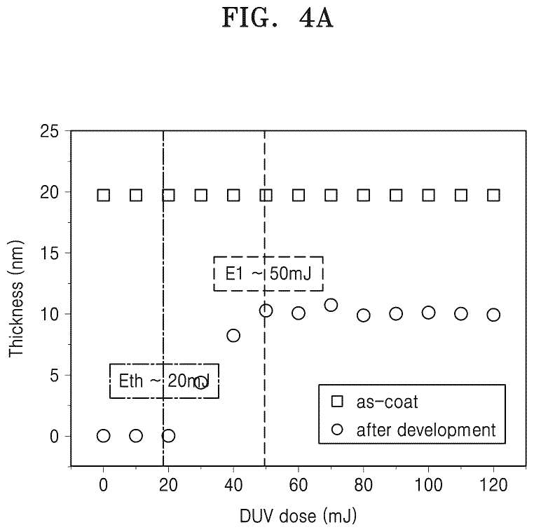

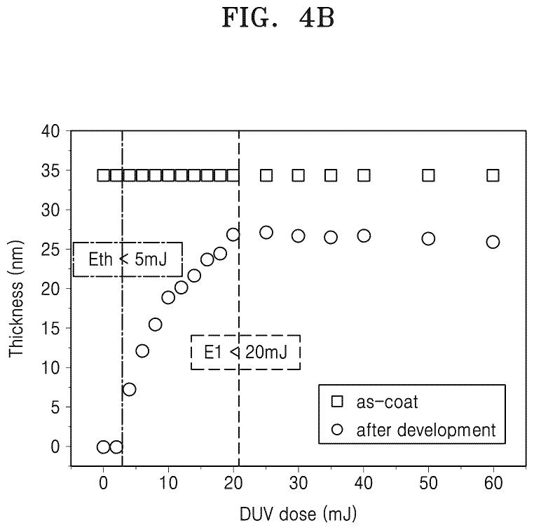

A P4VP polymer (Mw=60 kDa) and Compound T1 synthesized in Synthesis Example 2 were dissolved at a content of 2 wt % in a casting solvent shown in Table 1 below. In this case, a weight ratio of the polymer and the organometallic compound is as shown in Table 1 below. The casting solution was applied on a silicon wafer, on which hexamethyldisilazane (HMDS) was applied as a 3 nm lower film, at a speed of 1,500 rpm through spin coating, and then dried at a temperature of 120° C. for 1 minute to prepare films having initial thicknesses shown in Table 1 below. Then, the films having the initial thicknesses of Table 1 were exposed to DUV rays with a wavelength of 254 nm at a dose of 0 mJ/cm² to 60 mJ/cm² (Comparative Example 1 and Example 1), or were exposed to EUV with a wavelength of 13.5 nm at a dose of 0 mJ/cm² to 100 mJ/cm² (Comparative Example 2 and Example 2) and dried at a temperature of 150° C. to 200° C. for 1 minute. By using a PGMEA solution, in which an acetic acid was dissolved at a content of 2 wt % of, as a developing solution, the dried films were immersed therein at a temperature of 25° C. for 60 seconds to then measure thicknesses of the remaining films. Results thereof are shown in Table 2 and FIGS. 4A and 4B. FIGS. 4A and 4B are graphs of Comparative Example 1 and Example 1, respectively. In FIGS. 4A and 4B, “as-coat” is reference data about samples not treated with a developing solution, and “after develop” is data about samples treated with a developing solution.

TABLE 1

| | | | | | | Initial | | |
|---|---|---|---|---|---|---|---|---|
| | Organometallic | | Casting | Weight ratio | PAB | thickness | Light | PEB |
| | compound | Polymer | solvent | (T1:polymer) | (° C.) | (nm) | source | (° C.) |
| Comparative | T1 | — | Ethyl | — | 120 | 20 | DUV | 200 |
| Example 1 | | | lactate | | | | | |
| Example 1 | T1 | P4VP | Ethyl | 2:1 | 120 | 35 | DUV | 150 |
| | | (Mw = 60 | lactate | | | | | |
| | | kDa) | | | | | | |
| Comparative | T1 | — | Ethyl | — | 120 | 20 | EUV | 200 |
| Example 2 | | | lactate | | | | | |
| Example 2 | T1 | P4VP | Ethyl | 2:1 | 120 | 35 | EUV | 150 |
| | | (Mw = 60 | lactate | | | | | |
| | | kDa) | | | | | | |

TABLE 2

| | | | | | Remaining | |
|---|---|---|---|---|---|---|
| | Organometallic | | | | film ratio | |
| | compound | Polymer | Eₜₕ (mJ) | E₁ (mJ) | (%) | γ |
| Comparative | T1 | — | 20 | 50 | 50 | 2.5 |
| Example 1 | | | | | | |
| Example 1 | T1 | P4VP (Mw = 60 | 5 | 20 | 81 | 1.7 |
| | | kDa) | | | | |
| Comparative | T1 | — | 45 | 70 | NA | 5.2 |
| Example 2 | | | | | | |
| Example 2 | T1 | P4VP (Mw = 60 | 3 | 28 | NA | 1 |
| | | kDa) | | | | |

Referring to Table 2, it can be confirmed that Example 1 has smaller Eₜₕ and E₁ and exhibits a higher film remaining ratio as compared with than Comparative Example 1. Specifically, it could be confirmed that Eₜₕ, E₁, and the film remaining ratio of Example 1 were improved by about 4 times, about 2.5 times, and about 1.6 times as compared with Eₜₕ, E₁, and the film remaining ratio of Comparative Example 1, respectively.

In addition, referring to Table 2, it can be confirmed that Example 2 exhibits smaller Eₜₕ and E₁ than Comparative Example 2. Specifically, it could be confirmed that Eₜₕ and E₁ of Example 2 were been improved about 100 times and about 2.8 times as compared with Eₜₕ and E₁ of Comparative Example 2, respectively.

In addition, it can be confirmed that Example 1 and Example 2 exhibit higher y values than Comparative Example 1 and Comparative Example 2, respectively, which suggests that resist compositions of Example 1 and Example 2 have improved sensitivity as compared with resist compositions of Comparative Example 1 and Comparative Example 2, respectively.

### (3) Evaluation of Thin Film Development Over Time

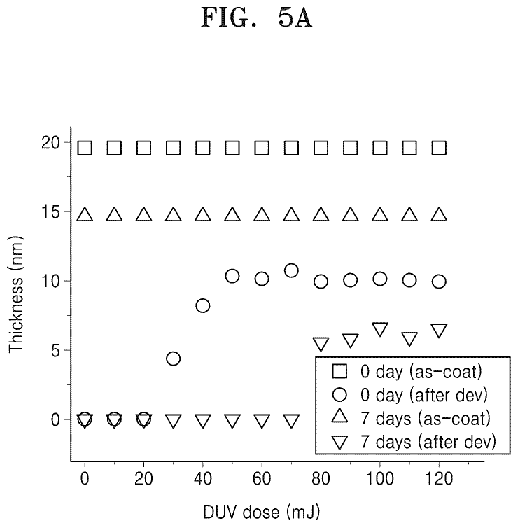

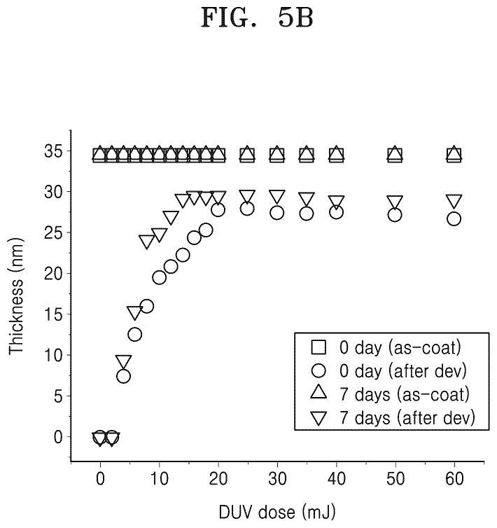

A P4VP polymer (Mw=60 kDa) and Compound T1 synthesized in Synthesis Example 2 were dissolved at a content of 2 wt % in a casting solvent shown in Table 1 below. In this case, a weight ratio of the polymer and the organometallic compound is as shown in Table 3 below. After an obtained casting solution was stored at room temperature for 7 days, the casting solution was applied on a silicon wafer, on which HMDS was applied as a 3 nm lower film, at a speed of 1,500 rpm through spin coating, and then dried at a temperature of 120° C. for 1 minute to obtain films of initial thicknesses of Table 3 below. Then, the films having the initial thicknesses of Table 3 were exposed to DUV rays with a wavelength of 254 nm at a dose of 0 mJ/cm² to 60 mJ/cm² and dried at a temperature of 150° C. to 200° C. for 1 minute. By using a PGMEA solution, in which an acetic acid was dissolved at a content of 2 wt %, as a developing solution, the dried films were immersed therein at a temperature of 25° C. for 60 seconds to then measure thicknesses of the remaining films. Results thereof are shown in Table 4 and FIGS. 5A and 5B. FIG. 5A is a graph of Comparative Example 1 (corresponding to 0 day in FIG. 5A) and Comparative Example 3 (corresponding to 7 days in FIG. 5A), and FIG. 5B is a graph of Example 1 (corresponding to 0 day in FIG. 5B) and Example 3 (corresponding to 7 days in FIG. 5B). In FIGS. 5A and 5B as-coat” is reference data about samples not treated with a developing solution, and “after dev” is data about samples treated with a developing solution.

In this case, a casting solution of Comparative Example 3 could not form a film having the same initial thickness as Example 3 due to the decomposition of Compound T1.

TABLE 3

| | | | | | | Initial | |
|---|---|---|---|---|---|---|---|
| | Organometallic | | Casting | Weight ratio | PAB | thickness | PEB |
| | compound | Polymer | solvent | (T1:polymer) | (° C.) | (nm) | (° C.) |
| Comparative | T1 | — | Ethyl | — | 120 | 15 | 200 |
| Example 3 | | | lactate | | | | |
| Example 3 | T1 | P4VP (Mw = 60 | Ethyl | 2:1 | 120 | 35 | 150 |
| | | kDa) | lactate | | | | |

TABLE 4

| | | | | | Remaining | |
|---|---|---|---|---|---|---|
| | Organometallic | | | | film ratio | |
| | compound | Polymer | Eₜₕ (mJ) | E₁ (mJ) | (%) | γ |
| Comparative | T1 | — | 70 | 80 | 47 | 17 |
| Example 3 | | | | | | |
| Example 3 | T1 | P4VP (Mw = 60 | 3 | 16 | 85 | 1.3 |
| | | kDa) | | | | |

Referring to Tables 2 and 4, it could be confirmed that Eₜₕ and E₁ of Comparative Example 3 were considerably increased as compared with Comparative Example 1, but Eₜₕ and E₁ of Example 3 were similar to or smaller than those of Example 1. That is, referring to Tables 2 and 4, it can be confirmed that a resist composition according to an embodiment of the disclosure has relatively high storage stability.

### (4) Evaluation of Thin Film Development According to Molecular Weight

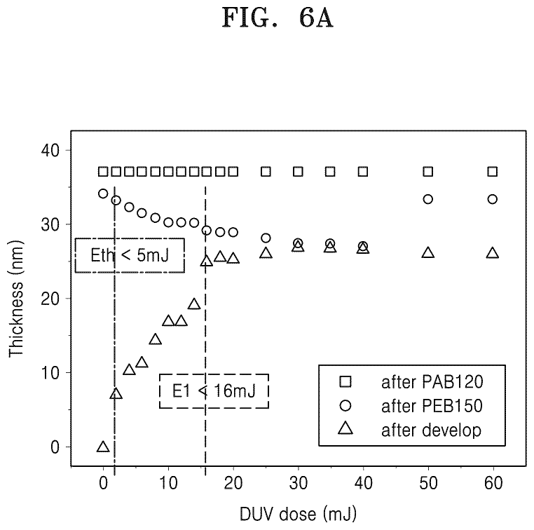

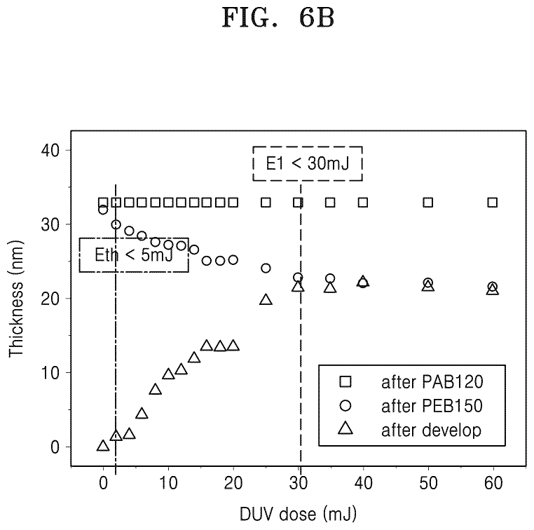

A P4VP polymer (Mw-60 kDa and PDI<1.2) and Compound T1 synthesized in Synthesis Example 2 were each dissolved at a content of 2 wt % in a casting solvent shown in Table 5 below. In this case, a weight ratio of the polymer and the organometallic compound is as shown in Table 5 below. A casting solution was applied on a silicon wafer, on which HMDS was applied as a 3 nm lower film, at a speed of 1,500 rpm through spin coating, and then dried at a temperature of 120° C. for 1 minute to prepare films having initial thicknesses shown in Table 5 below. Then, the films were exposed to DUV rays with a wavelength of 254 nm at a dose of 0 mJ/cm² to 60 mJ/cm² and dried at a temperature of 150° C. to 200° C. for 1 minute. By using a PGMEA solution, in which an acetic acid was dissolved at a content of 2 wt %, as a developing solution, the dried films were immersed therein at a temperature of 25° C. for 60 seconds to then measure thicknesses of the remaining films. Results thereof are shown in Table 6 and FIGS. 6A and 6B. FIGS. 6A and 6B are graphs of Example 4 and Example 5, respectively. In FIGS. 6A and 6B, “after PAB 120” is reference data about samples dried at a temperature of 120° C. for 1 minute and not treated with a developing solution, “after PEB 150” is reference data about samples not treated with a developing solution but dried at a temperature of 150° C. for 1 minute, and “after develo” is data about samples treated with a developing solution.

TABLE 5

| | Organometallic | | Casting | Weight ratio | PAB | Initial thickness | PEB |
|---|---|---|---|---|---|---|---|
| | compound | Polymer | solvent | (T1:polymer) | (° C.) | (nm) | (° C.) |
| Comparative | T1 | — | Ethyl | — | 120 | 20 | 200 |
| Example 1 | | | lactate | | | | |
| Example 4 | T1 | P4VP | Ethyl | 3:1 | 120 | 35 | 150 |
| | | (Mw = 6 | lactate | | | | |
| | | kDa and | | | | | |
| | | PDI < 1.2) | | | | | |
| Example 5 | T1 | P4VP | Ethyl | 5:1 | 120 | 35 | 150 |
| | | (Mw = 6 | lactate | | | | |
| | | kDa and | | | | | |
| | | PDI < 1.2) | | | | | |

TABLE 6

| | Organometallic | | | | Remaining film | |
|---|---|---|---|---|---|---|
| | compound | Polymer | Eₜₕ (mJ) | E₁ (mJ) | ratio (%) | γ |
| Comparative | T1 | — | 20 | 50 | 50 | 2.5 |
| Example 1 | | | | | | |
| Example 4 | T1 | P4VP (Mw = 6 | 5 | 16 | 70 | 2 |
| | | kDa and | | | | |
| | | PDI < 1.2) | | | | |
| Example 5 | T1 | P4VP (Mw = 6 | 5 | 30 | 65 | 1.3 |
| | | kDa and | | | | |
| | | PDI < 1.2) | | | | |

Referring to Table 6, it can be confirmed that Example 4 and Example 5 have smaller Eₜₕ and E₁ and show a higher film remaining ratio as compared with Comparative Example 1. In addition, it can be confirmed that Examples 4 and 5 exhibit higher y values than Comparative Example 1, which suggests that resist compositions of Examples 4 and 5 each have improved sensitivity as compared with the resist composition of Comparative Example 1.

Embodiments may provide a resist composition having improved sensitivity and providing a pattern with improved resolution.

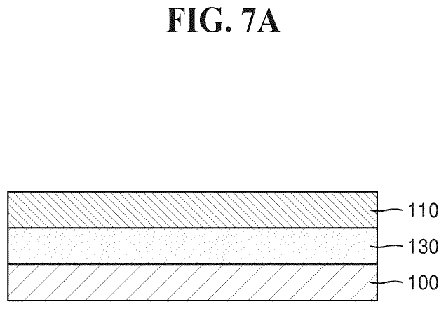

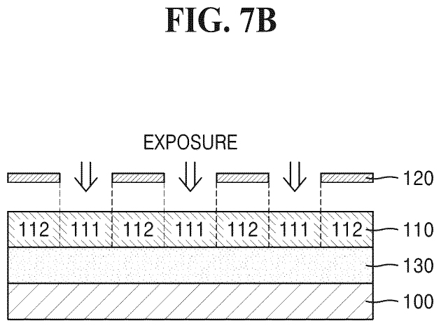

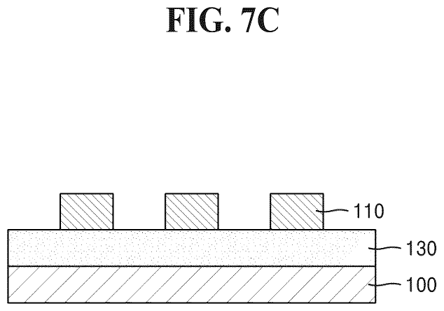

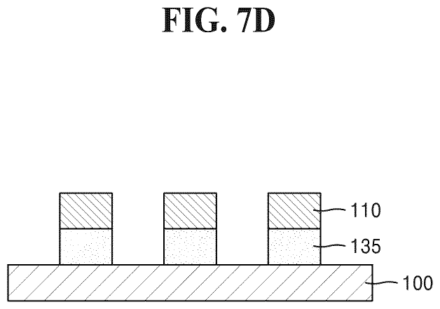

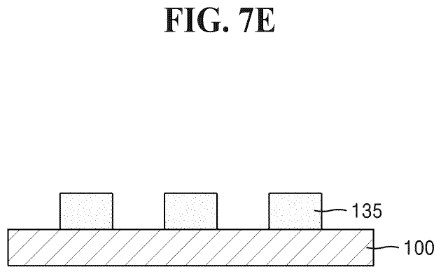

FIGS. 7A to 7E are side cross-sectional views illustrating a method of forming a patterned structure according to an embodiment.

Referring to FIG. 7A, a material layer 130 may be formed on the substrate 100 before forming a resist film 110 on the substrate 100. The resist film 110 may be formed on top of the material layer 130. The material layer 130 may include an insulating material (e.g., silicon oxide, silicon nitride), a semiconductor material (e.g., silicon), a metal (e.g., copper). In some embodiments, the material layer 130 may be a multi-layer structure. A material of the material layer 130 may be different than a material of the substrate 100.

Referring to FIG. 7B, the resist film 110 may undergo a pre-exposure bake process and may be exposed with high energy rays through a mask 120, after which the resist film 110 may include exposed regions 111 and unexposed regions 112.

Referring to FIG. 7C, the exposed resist film 110 may be developed using a developer (e.g., developing solution). The exposed area 111 may be washed away by the developer and the unexposed area 112 may remain without being washed away by the developer.

Referring to FIG. 7D, exposed areas of the material layer 130 may be etched using the resist pattern 110 as a mask to form a material pattern 135 on the substrate 100.

Referring to FIG. 7E, the resist pattern 110 may be removed.

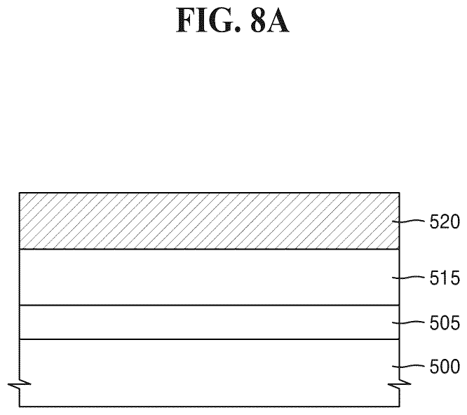

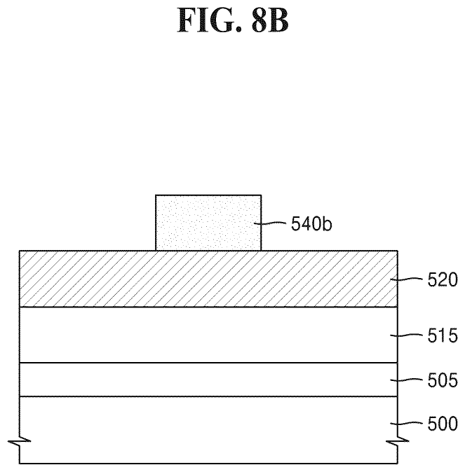

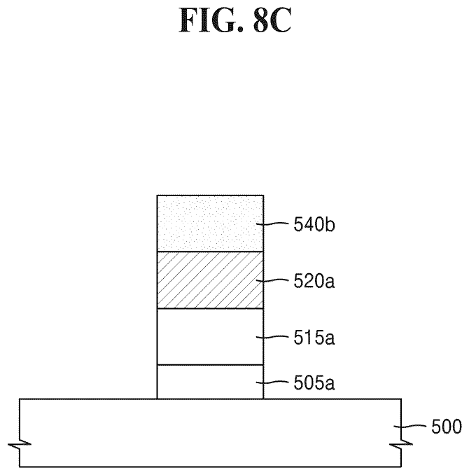

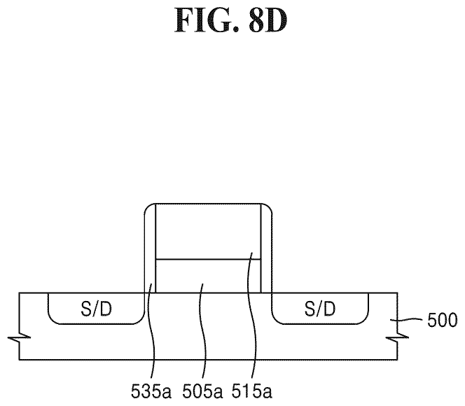

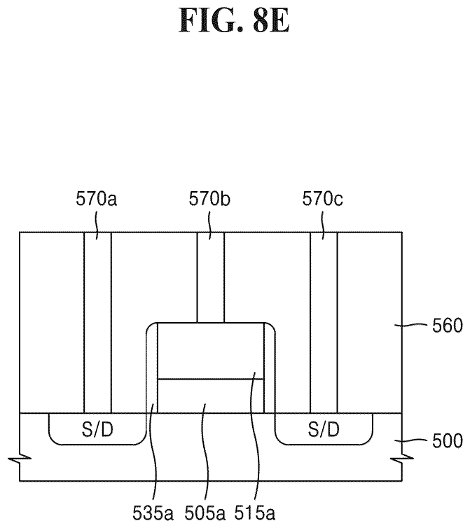

FIGS. 8A to 8E are side cross-sectional views illustrating a method of forming a semiconductor device according to an embodiment.

Referring to FIG. 8A, a gate dielectric 505 (e.g., silicon oxide) may be formed on a substrate 500. The substrate 500 may be a semiconductor substrate, such as a silicon substrate. A gate layer 515 (e.g., doped polysilicon) may be formed on the gate dielectric 505. A hardmask layer 520 may be formed on the gate layer 515.

Referring to FIG. 8B, a resist pattern 540b may be formed on the hardmask layer 520. The resist pattern 540b may be formed using a resist composition according to example embodiments. The resist composition may include an organic solvent.

Referring to FIG. 8C, the gate layer 515 and the gate dielectric 505 may be etched to form a hardmask pattern 520a, a gate electrode pattern 515a, and a gate dielectric pattern 505a.

Referring to FIG. 8D, a spacer layer may be formed over the gate electrode pattern 515a and the gate dielectric pattern 505a. The spacer layer may be formed using a deposition process (e.g., CVD). The spacer layer may be etched to form spacers 535a (e.g., silicon nitride) on sidewalls of the gate electrode pattern 515a and the gate dielectric pattern 505a. After forming the spacers 535a, ions may be implanted into the substrate 500 to form source/drain impurity regions S/D.

Referring to FIG. 8E, an interlayer insulating layer 560 (e.g., oxide) may be formed on the substrate 500 to cover the gate electrode pattern 515a, gate dielectric pattern 505a, and spacers 535a. Then, electrical contacts 570a, 570b, and 570c may be formed in the interlayer insulating layer 560 to connect to the gate electrode 515a and the S/D regions. The electrical contacts may be formed of a conductive material (e.g., metal). Although not illustrated, a barrier layer may be formed between sidewalls of the interlayer insulating layer 560 and the electrical contacts 570a, 570b, and 570c. While FIGS. 8A to 8E illustrate an example of forming a transistor, inventive concepts are not limited thereto. A resist composition according to one or more embodiments may be used in a patterning process to form other types of semiconductor devices. The resist composition may include an organic solvent.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A resist composition comprising:
an organometallic compound represented by Formula 1 below; and
a polymer comprising a repeating unit represented by Formula 2 below: 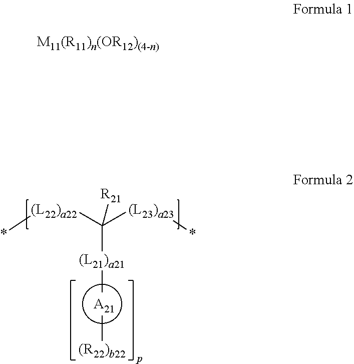
wherein, in Formula 1 and Formula 2,
M₁₁ is indium (In), tin (Sn), antimony (Sb), tellurium (Te), thallium (Tl), lead (Pb), bismuth (Bi), silver (Ag), or polonium (Po),
R₁ is a linear, branched, or cyclic C₁-C₃₀ monovalent hydrocarbon group optionally containing a heteroatom,
R₁₂ is a linear, branched, or cyclic C₁-C₃₀ monovalent hydrocarbon group optionally containing a heteroatom, or *-M₁₂(R₁₃)ₘ(OR₁₄)₍₃₋ₘ₎,
n is an integer from 1 to 4,
M₁₂ is indium (In), tin (Sn), antimony (Sb), tellurium (Te), thallium (Tl), lead (Pb), bismuth (Bi), silver (Ag), or polonium (Po),
R₁₃ and R₁₄ are each independently a linear, branched, or cyclic C₁-C₃₀ monovalent hydrocarbon group optionally containing a heteroatom,
m is an integer from 0 to 3,
L₂₁ to L₂₃ are each independently: a single bond; O; S; C(═O); C(═O)O; OC(═O); C(═O)NH, NHC(═O); or a linear, branched, or cyclic C₁-C₃₀ divalent hydrocarbon group optionally containing a heteroatom,
a21 to a23 are each independently an integer from 1 to 4,
A₂₁ is a cyclic C₁-C₃₀ hydrocarbon group containing a heteroatom,
R₂₁ and R₂₂ are each independently hydrogen; deuterium; halogen; or a linear, branched, or cyclic C₁-C₃₀ monovalent hydrocarbon group optionally containing a heteroatom,
b22 is an integer of 1 to 10,
p is an integer of 1 to 5, and
* is a binding site with an adjacent atom.

2. The resist composition of claim 1, wherein
a bond between M₁₁ and R₁₁ is an M₁₁-carbon single bond,
R₁₂ is *-M₁₂(R₁₃)ₘ(OR₁₄)₍₃₋ₘ₎,
n is an integer of 1 to 3, and
a bond between M₁₂ and R₁₃ is an M₁₂-carbon single bond.

3. The resist composition of claim 1, wherein the organometallic compound has a molecular weight of about 3,000 g/mol or less.

4. The resist composition of claim 1, wherein M₁₁ and M₁₂ are each independently Sn, Sb, Te, Bi, or Ag.

5. The resist composition of claim 1, wherein
R₁₁ and R₁₃ are each independently represented by *-(L₁₁)ₐ₁₁-X₁₁,
R₁₂ and R₁₄ are each independently represented by *-(L₁₂)ₐ₁₂-X₁₂,
L₁₁ and L₁₂ are each independently CRₐR_{b}, C═O, S═O, SO₂, PO₂, PO₃, or NO₂,
a11 and a12 are each independently an integer from 0 to 3,
X₁₁ and X₁₂ are each independently a substituted or unsubstituted C₁-C₃₀ alkyl group, a substituted or unsubstituted C₁-C₃₀ halogenated alkyl group, a substituted or unsubstituted C₁-C₃₀ alkoxy group, a substituted or unsubstituted C₁-C₃₀ alkylthio group, a substituted or unsubstituted C₁-C₃₀ halogenated alkoxy group, a substituted or unsubstituted C₁-C₃₀ halogenated alkylthio group, a substituted or unsubstituted C₃-C₃₀ cycloalkyl group, a substituted or unsubstituted C₃-C₃₀ cycloalkoxy group, a substituted or unsubstituted C₃-C₃₀ cycloalkylthio group, a substituted or unsubstituted C₃-C₃₀ heterocycloalkyl group, a substituted or unsubstituted C₃-C₃₀ heterocycloalkoxy group, a substituted or unsubstituted C₃-C₃₀ heterocycloalkylthio group, a substituted or unsubstituted C₂-C₃₀ alkenyl group, a substituted or unsubstituted C₂-C₃₀ alkenyloxy group, a substituted or unsubstituted C₂-C₃₀ alkenylthio group, a substituted or unsubstituted C₃-C₃₀ cycloalkenyl group, a substituted or unsubstituted C₃-C₃₀ cycloalkenyloxy group, a substituted or unsubstituted C₃-C₃₀ cycloalkenylthio group, a substituted or unsubstituted C₃-C₃₀ heterocycloalkenyl group, a substituted or unsubstituted C₃-C₃₀ heterocycloalkenyloxy group, a substituted or unsubstituted C₃-C₃₀ heterocycloalkenylthio group, a substituted or unsubstituted C₂-C₃₀ alkynyl group, a substituted or unsubstituted C₂-C₃₀ alkynyloxy group, a substituted or unsubstituted C₂-C₃₀ alkynylthio group, a substituted or unsubstituted C₆-C₃₀ aryl group, a substituted or unsubstituted C₆-C₃₀ aryloxy group, a substituted or unsubstituted C₆-C₃₀ arylthio group, a substituted or unsubstituted C₁-C₃₀ heteroaryl group, a substituted or unsubstituted C₁-C₃₀ heteroaryloxy group, or a substituted or unsubstituted C₁-C₃₀ heteroarylthio group,
Rₐ and R_{b} are each independently hydrogen, deuterium, a hydroxyl group, a cyano group, a nitro group, a substituted or unsubstituted C₁-C₃₀ alkyl group, a substituted or unsubstituted C₁-C₃₀ alkoxy group, a substituted or unsubstituted C₁-C₃₀ alkylthio group, a substituted or unsubstituted C₃-C₃₀ cycloalkyl group, a substituted or unsubstituted C₃-C₃₀ cycloalkoxy group, or a substituted or unsubstituted C₃-C₃₀ cycloalkylthio group, and
* is a binding site with an adjacent atom.

6. The resist composition of claim 1, wherein the organometallic compound is represented by any one of Formulas 1-1 to 1-16 below: 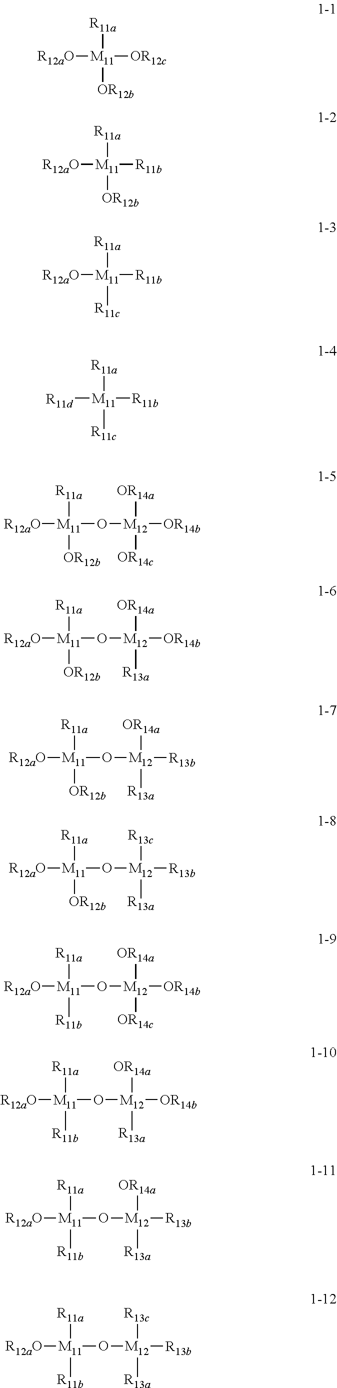 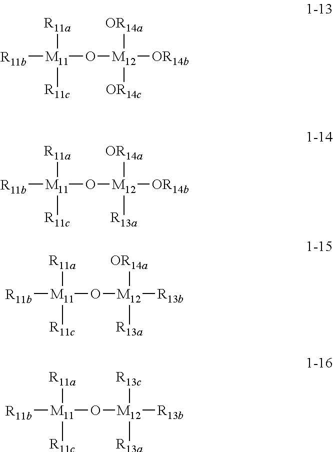
wherein, in Formulas 1-1 to 1-16,
M₁₁ and M₁₂ are each defined as in Formula 1,
a definition of each of R₁₁ₐ to R_{11d} is identical to a definition of R₁₁ in Formula 1,
a definition of each of R₁₂ₐ to R_{12c} is identical to a definition of R₁₂ in Formula 1,
a definition of each of R₁₃ₐ to R_{13c} is identical to a definition of R₁₃ in Formula 1, and
a definition of each of R₁₄ₐ to R_{14c} is identical to a definition of R₁₄ in Formula 1.

7. The resist composition of claim 1, wherein the polymer does not comprise a repeating unit of which a structure is changed by an acid.

8. The resist composition of claim 1, wherein A₂₁ comprises a lone-pair electron pair.

9. The resist composition of claim 1, wherein A₂₁ comprises an oxygen atom, a sulfur atom, a nitrogen atom, a phosphorus atom, or any combination thereof as the heteroatom.

10. The resist composition of claim 1, wherein A₂₁ comprises an oxygen atom, a sulfur atom, a nitrogen atom, a phosphorus atom, S═O, P═O, C═O, or any combination thereof as a partial structure.

11. The resist composition of claim 1, wherein A₂₁ is:
a C₃-C₂₀ heterocycloalkyl group comprising an oxygen atom, a sulfur atom, a nitrogen atom, or any combination thereof;
a C₃-C₂₀ heterocycloalkenyl group comprising an oxygen atom, a sulfur atom, a nitrogen atom, or any combination thereof;
a pyrrole group;
a furan group;
a thiophene group;
an imidazole group;
an oxazole group;
a thiazole group;
a pyridine group;
a pyrazine group;
a triazine group;
a quinoline group;
an isoquinoline group;
a benzoquinoline group;
a quinoxaline group;
a quinazoline group;
a cinnoline group;
a phenanthroline group;
a phenanthridine group;
an indole group;
a benzofuran group;
a benzothiophene group;
a benzimidazole group;
a benzooxazole group;
a benzothiazole group;
a carbazole group;
a dibenzofuran group; or
a dibenzothiophene group.

12. The resist composition of claim 1, wherein a content of the organometallic compound is in a range of about 10 parts by weight to about 1,000 parts by weight with respect to about 100 parts by weight of the polymer.

13. The resist composition of claim 1, wherein the polymer has a weight average molecular weight (Mw) of about 1,000 to about 500,000.

14. The resist composition of claim 1, further comprising:
an organic solvent, a surfactant, a crosslinking agent, a leveling agent, a colorant, or any combination thereof.

15. A method of forming a pattern, the method comprising:
applying the resist composition of claim 1 to form a resist film;
exposing at least a portion of the resist film to high energy rays to provide an exposed resist film; and
developing the exposed resist film using a developing solution.

16. The method of claim 15, wherein the exposing is performed by irradiating the at least a portion of the resist film with at least one of ultraviolet rays, deep ultraviolet (DUV) rays, extreme ultraviolet (EUV) rays, X-rays, γ-rays, electron beams (EBs), or α-rays.

17. The method of claim 15, wherein the exposing the at least a portion of the resist film forms a chemical bond between the organometallic compound and the polymer.

18. The method of claim 15, wherein
the exposed resist film comprises an exposed portion and an unexposed portion, and
the developing the exposed resist film includes removing the unexposed portion.

19. A resist composition comprising:
an organometallic compound represented by Formula 1 below; and
a monomer represented by Formula 20 below: 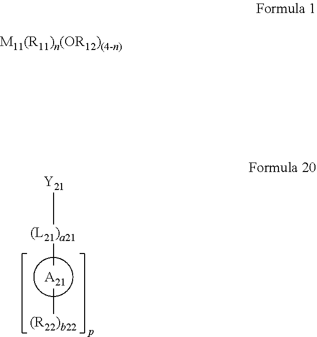
wherein, in Formula 1 and Formula 20,
M₁₁ is indium (In), tin (Sn), antimony (Sb), tellurium (Te), thallium (Tl), lead (Pb), bismuth (Bi), silver (Ag), or polonium (Po),
R₁ is a linear, branched, or cyclic C₁-C₃₀ monovalent hydrocarbon group optionally containing a heteroatom,
R₁₂ is a linear, branched, or cyclic C₁-C₃₀ monovalent hydrocarbon group optionally containing a heteroatom, or *-M₁₂(R₁₃)ₘ(OR₁₄)₍₃₋ₘ₎,
n is an integer from 1 to 4,
M₁₂ is indium (In), tin (Sn), antimony (Sb), tellurium (Te), thallium (Tl), lead (Pb), bismuth (Bi), silver (Ag), or polonium (Po),
R₁₃ and R₁₄ are each independently a linear, branched, or cyclic C₁-C₃₀ monovalent hydrocarbon group optionally containing a heteroatom,
m is an integer from 0 to 3,
Y₂₁ is a polymerizable group,
L₂₁ is a single bond, O, S, C(═O), C(═O)O, OC(═O), C(═O)NH, NHC(═O), or a linear, branched, or cyclic C₁-C₃₀ divalent hydrocarbon group optionally containing a heteroatom,
a21 is an integer from 1 to 4,
A₂₁ is a cyclic C₁-C₃₀ hydrocarbon group containing a heteroatom,
R₂₂ is: hydrogen; deuterium; halogen; or a linear, branched, or cyclic C₁-C₃₀ monovalent hydrocarbon group optionally containing a heteroatom,
b22 is an integer from 1 to 10, and
p is an integer from 1 to 5.

20. The resist composition of claim 19, wherein Y₂₁ comprises a vinyl group, an acrylate group, a methacrylate group, an oxirane group, an epoxy group, an oxetane group, a thiol group, or any combination thereof as a partial structure.
